(19) United States
(12) Patent Application Publication
(10) Pub. No.: US 2022/0342308 A1
(43) Pub. Date: Oct. 27, 2022

(54) POSITIVE WORKING PHOTOSENSITIVE MATERIALS

(71) Applicant: Merck Patent GmbH, Darmstadt (DE)

(72) Inventors: Weihong LIU, Branchburg, NJ (US); Ping-Hung LU, Bridgewater, NJ (US)

(21) Appl. No.: 17/762,497

(22) PCT Filed: Nov. 11, 2020
(86) PCT No.: PCT/EP2020/081706

§ 371 Date: Mar. 22, 2022

Related U.S. Application Data
(60) Provisional application No. 62/935,324, filed on Nov. 14, 2019.
(60) Provisional application No. 62/934,614, filed on Nov. 13, 2019.

(51) Int. Cl. G03F 7/039; G03F 7/023; G03F 7/022

(52) U.S. Cl. CPC G03F 7/0397; G03F 7/0233; G03F 7/0226

(57) ABSTRACT

Disclosed herein is a photosensitive composition comprising a DNQ-PAC, a heterocyclic thiol compound or tautomeric form thereof, an acrylate polymer, a Novolak and a PAG and its method of use on a substrate which may include a chalcophile substrate.

### FIELD OF THE INVENTION

The present application for patent is in the field of photoresist imaging. More specifically, the present application for patent discloses and claims a positive working photosensitive material which may, without limitation, be useful on chalcophilic or reflective substrates.

### BACKGROUND

In the field of electronic device manufacturing, imaging materials must be made to perform on a variety of substrates. It is known in the art that different substrates may pose different challenges. For example, reflective, highly conductive substrates may impose optical conditions within the imageable films that lead to phenomena such as scumming, footing, standing wave artifacts such as “scallops” and the like. Further, interfacial issues may arise from poor adhesion. Poor adhesion may result in undercutting or delamination of the film during development. On the other hand, the film may exhibit strong adhesion to certain types of substrates that may result in foot formation or scumming.

There have been several attempts to manage the above optical and interfacial phenomena. To improve adhesion, substrate treatments have been described. For example, U.S. Pat. No. 4,956,035 discloses “a composition for promoting the adhesion of an organic compound to a metal surface, which comprises an etching solution, an effective amount of a quaternary ammonium cationic surfactant, and a solubilizing amount of a secondary surfactant or solvent.” This composition is said to be useful for improving photoresist adhesion to copper-clad circuit boards, and for improving adhesion of solder masks to printed circuits. However, while this treatment may be effective on such substrates as copper-clad circuit boards, its utility may be problematic on semiconductor substrates which require much more precision, particularly where etch chemistries may be involved.

As a further example, U.S. Pat. Appl. No. 2011/0214994 discloses a “pretreating agent for electroplating pertaining to the present invention [which] is characterized in that it includes an aqueous solution containing: (A) at least one anti-adsorption agent selected from among a triazole compound, a pyrazole compound, an imidazole compound, a cationic surfactant and an amphoteric surfactant; and (B) chloride ion as essential ingredients.” The pretreating agent may also contain a nonionic surfactant, and at least one solvent selected from among water-soluble ethers, amines, alcohols, glycol ethers, ketones, esters, and fatty acids, and an acid, and an oxidizing agent. While this formulation contains ingredients that arguably perform an anti-adsorption function, its use may be incompatible with semiconductor processing because it adds an extra step and requires a separate feed stream.

Therefore, there remains a need for a positive working photosensitive material with a composition suited for imaging on reflective and chalcophilic substrates that produces low defect images at high resolution. As will become apparent, the subject matter disclosed herein addresses the above need.

### SUMMARY

In one aspect this invention pertains to a composition comprising components a), b), c), d), and e):
a) at least one Diazonaphthoquinonesulfonate Photoactive Compound (DNQ-PAC),
b) at least one heterocyclic thiol having structure (7), (8) and/or (9),
c) at least one photoacid generator;
d) at least one acrylic polymer comprising repeat units selected from ones having structure (1), (2), (3), (4), (5), and (6),
e) at least one Novolak polymer having a dissolution rate in 0.26 N tetramethylammonium hydroxide at 23° C. of at least 50 Å/sec, wherein
   said repeat units are present in said acrylic polymer in the following mole % ranges, based on the total moles of all different repeat units present, and further where the summation of the individual mole % values for all repeat units present in said polymer must equal 100 mole %, and

(1) ranges from about 0 to about 35 mole %

(2) ranges from about 5 to about 55 mole %

(3) ranges from about 0 to about 30 mole %

(4) ranges from about 15 to about 55 mole %

(5) ranges from about 10 to about 40 mole %,

(6) ranges from about 0 to about 25 mole %, and

R₁, R₂, R₃, R₄, R₅, and R₆ are individually selected from either H, F, a C-1 to C-4 fluoroalkyl, or a C-1 to C-4 alkyl

R₇ is selected from H, a C-1 to C-4 alkyl, a C-1 to C-4 alkyloxy alkyl, and a halogen,

R₈ is a C-3 to C-8 cyclic alkyl, or a C-7 to C-14 alicyclic alkyl,

R₉ is a C-2 to C-8 (hydroxy)alkylene moiety,

R₁₀ is an acid cleavable group,

R₁₁ is a C-3 to C-12, (alkyloxy)alkylene moiety; and

in said heterocyclic thiol for said structure (7), Xt is selected from the group consisting of C(Rt₁)(Rt₂), O, S, Se, and Te; for said structure (8), Y is selected from the group consisting of C(Rt₃) and N; for said structure (9), Z is selected from the group consisting of C(Rt₃) and N; and

Rt₁, Rt₂, and Rt₃ are independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms;

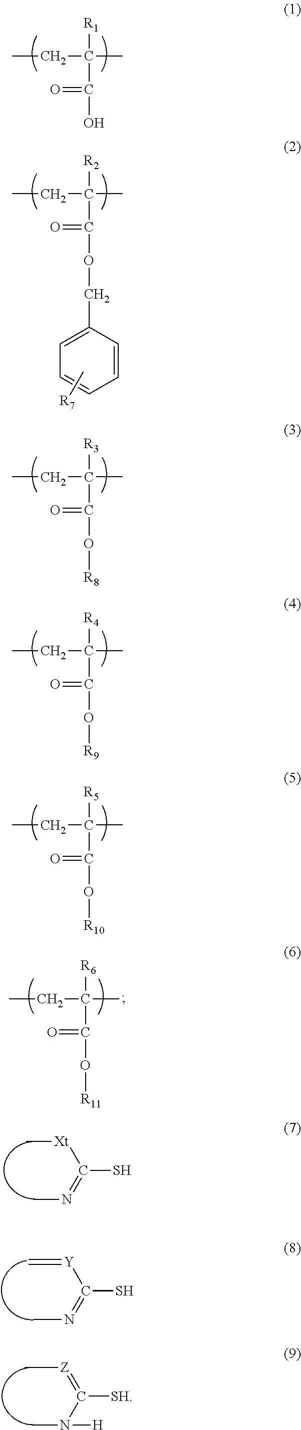

Another aspect of this invention is a method of forming a positive relief image using said inventive compositions. Yet another aspect of this invention is the use of the composition according to the invention for forming a positive relief image on a substrate.

### DETAILED DESCRIPTION

As used herein, the conjunction “or” is not intended to be exclusive unless otherwise indicated or required by the context. For example, the phrase “or, alternatively” is intended to be exclusive. As a further example, “or” may be exclusive when describing chemical substitution at a specific site.

As used herein, the term “chalcophile” is an element that has an affinity for the chalcogen elements, sulfur, selenium and tellurium. Other than the chalcogens themselves, these elements may include copper, zinc, gallium, germanium, arsenic, silver, cadmium, lanthanum, tin, antimony, gold, mercury, thallium, lead, and bismuth. Without limitation, these elements may form bonds with one or more of the chalcogen elements that are primarily covalent in character. A chalcophile substrate comprises one or more of the above listed chalcophiles.

As used herein, it is understood that a repeat unit within a polymer may be referred to by its corresponding monomer. For example, acrylate monomer (I) corresponds to its polymer repeat unit (II).

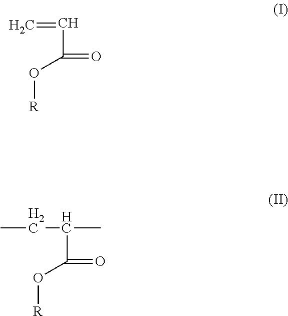

As used herein, the designation “(meth)acrylate repeat unit” may refer to an acrylate repeat unit or, alternatively, a methacrylate repeat unit. Accordingly, “acrylic acid” and “methacrylic acid” are collectively referred to as “(meth)acrylic acid,” an “acrylic acid derivative” and a “methacrylic acid derivative” are collectively referred to as a “(meth)acrylic acid derivative,” and “acrylate” and “methacrylate” are collectively referred to as “(meth)acrylate.”

Herein, unless otherwise indicated, “alkyl” refers to hydrocarbon groups which can be linear, branched (e.g., methyl, ethyl, propyl, isopropyl, tert-butyl and the like) or cyclic (e.g., cyclohexyl, cyclopropyl, cyclopentyl and the like) multicyclic (e.g., norbornyl, adamantly and the like). These alkyl moieties may be substituted or unsubstituted as described below. The term alkyl refers to such moieties with C-1 to C-20 carbons. It is understood that for structural reasons linear alkyls start with C-1, while branched alkyls and cyclic alkyls start with C-3 and multicyclic alkyls start with C-5. Moreover, it is further understood that moieties derived from alkyls described below such as alkyloxy, haloalkyloxy have the same carbon number ranges unless otherwise indicated. If the length of the alkyl group is specified as other than described above, the above described definition of alkyl still stands with respect to it encompassing all types of alkyl moieties as described above and that the structural consideration with regards to minimum number of carbons for a given type of alkyl group still apply. Herein, the specific designation in R₈ for a C-3 to C-8 cyclic alkyl, or a C-7 to C-14 alicyclic alkyl, refers to only such moieties which as carboxylate esters with the oxygen of the (meth)acrylate repeat unit of structure (3) do not form a carboxylate bond which can be easily cleaved acidolytically by a photoacid generator during normal photo-lithographic processing of resist films. Thus, this designation excludes tertiary attachment points with available beta hydrogen for an elimination of the carboxylate which can form through acidolysis (a.k.a. catalysis by H⁺ only) a stable tertiary carbocation capable of easily forming by elimination an olefin, a (meth)acrylic acid moiety and regenerating H⁺).

“Alkyloxy” (a.k.a. Alkoxy) refers to an alkyl group as defined above which is attached through an oxy (—O—) moiety (e.g., methoxy, ethoxy, propoxy, butoxy, 1,2-isopropoxy, cyclopentyloxy cyclohexyloxy and the like). These alkyloxy moieties may be substituted or unsubstituted as described below.

“Halo” or “halide” refers to a halogen, F, Cl, Br, I which is linked by one bond to an organic moiety.

“Haloalkyl” refers to a linear, cyclic or branched saturated alkyl group such as defined above in which at least one of the hydrogens has been replaced by a halide selected from the group consisting of F, Cl, Br, I or mixture of these if more than one halo moiety is present. Fluoroalkyls are a specific subgroup of these moieties.

“Fluoroalkyl” refers to a linear, cyclic or branched saturated alkyl group as defined above in which the hydrogens have been replaced by fluorine either partially or fully (e.g., trifluoromethyl, pefluoroethyl, 2,2,2-trifluoroethyl, prefluoroisopropyl, perfluorocyclohexyl and the like). These fluoroalkyl moieties, if not perfluorinated, may be substituted or unsubstituted as described below.

“Fluoroalkyloxy” refers to a fluoroalkyl group as defined above on which is attached through an oxy (—O—) moiety it may be completed fluorinated (a.k.a. perfluorinated) or alternatively partially fluorinated (e.g., trifluoromethyoxy, perfluoroethyloxy, 2,2,2-trifluoroethoxy, perfluorocyclohexyloxy and the like). These fluoroalkyl moieties, if not pefluorinated may, be substituted or unsubstituted as described below.

Herein when referring to an alkyl, alkyloxy, fluoroalkyl, fluoroalkyloxy moieties with a possible range of carbon atoms which starts with C-1 such as for instance “C-1 to C-20 alkyl,” or “C-1 to C-20 fluoroalkyl,” as non-limiting examples, this range encompasses linear alkyls, alkyloxy, fluoroalkyl and fluoroalkyloxy starting with C-1 but only designates branched alkyls, branched alkyloxy, cycloalkyl, cycloalkyloxy, branched fluoroalkyl, and cyclic fluoroalkyl starting with C-3. Similarly, the terms “C-1 to C-4 alkyl,” and “C-1 to C-4 alkyloxy,” designates a group which includes C-1 to C-4 linear alkyl moities but also C-3 branched alkyl or C-3 cyclic alkyl moieties.

Herein the term “alkylene” refers to hydrocarbon groups which can be a linear, branched or cyclic which has two or more attachment points (e.g., of two attachment points: methylene, ethylene, 1,2-isopropylene, a 1,4-cyclohexylene and the like; of three attachment points 1,1,1-substituted methane, 1,1,2-substituted ethane, 1,2,4-substituted cyclohexane and the like). Here again, when designating a possible range of carbons, such as C-1 to C-20, as a non-limiting example, this range encompasses linear alkylenes starting with C-1 but only designates branched alkylenes, or cycloalkylene starting with C-3. These alkylene moieties may be substituted or unsubstituted as described below.

The terms “mono alkyleneoxyalkylene” and “oligomeric alkyleneoxyalkylene” encompasses both simple alkyleneoxyalkylene moiety such as ethyleneoxyethylene (—CH₂—CH₂—O—CH₂—CH₂—), propyleneoxypropylene (—CH₂—CH₂—CH₂—O—CH₂—CH₂—CH₂—), and the like, and also oligomeric materials such as tri(ethyleneoxyethylene) (—CH₂—CH₂—O—CH₂—CH₂—O—CH₂—CH₂—), tri(propyleneoxypropylen), (—CH₂—CH₂—CH₂—O—CH₂—CH₂—CH₂—O CH₂—CH₂—CH₂—), and the like.

Herein the term “aryl group” or “aromatic group” refers to such groups which contain 6 to 24 carbon atoms including phenyl, tolyl, xylyl, naphthyl, anthracyl, biphenyls, bis-phenyls, tris-phenyls and the like. These aryl groups may further be substituted with any of the appropriate substituents e.g., alkyl, alkoxy, acyl or aryl groups mentioned hereinabove.

The term “Novolak” if used herein without any other modifier of structure, refers to Novolak resins which are soluble in aqueous bases such as tetramethylammonium hydroxide and the like.

Herein, the term “PAG,” unless otherwise described, refers to a photoacid generator that can generate acid (a.k.a. photoacid) under deep UV or UV irradiation such as 200-300 nm, i-line, h-line, g-line and/or broadband irradiation. The acid may be a sulfonic acid, HCl, HBr, HAsF₆, and the like.

Herein, the term “PAC” refers to a diazonaphthoquinone component wherein this moiety is further substituted with a sulfonyl moiety (—SO₂—) that is attached to a phenolic compound through a sulfonate ester (—SO₂—O—) bound. The phenolic compound forming this sulfonate ester bond may be a phenolic compound substituted with more than one phenolic OH moiety, and consequently, the PAC may be such a phenolic compound wherein more than one of the phenol OH form this sulfonate bond. Non-limiting examples of these free PAC materials are described in “Diazonapthoquinone-based Resist, Ralph Dammel, SPIE, Optical Engineering Press, Volume TT 11, Chapters 2 and 3.

The use of the term, “substituted aryl,” entails that the substituent is selected from any of the above described substituents. Similarly, the term “unsubstituted aryl” specifies that no substituents apart from hydrogen is present.

The term “quencher,” refers to an assembly of basic components, such as amines, or other lewis bases (e.g., basic anions such as carboxylate anion in a carboxylate salt such as tetraalkylammonium) which in a resist formulation could act to capture an acid generated by a photoacid generator during exposure to i-line or broadband radiation.

The term “wt % solids,” refers to the wt % of each non solvent components in a photoresist formulation based on the total weight of non-solvent components. Such components may be solids or liquids.

In one aspect this invention pertains to a composition comprising components a), b), c), d), and e):
a) at least one Diazonaphthoquinonesulfonate Photoactive Compound (DNQ-PAC),
b) at least one heterocyclic thiol having structure (7), (8) and/or (9),
c) at least one photoacid generator;
d) at least one acrylic polymer comprising repeat units selected from ones having structure (1), (2), (3), (4), (5), and (6),
e) at least one Novolak polymer having a dissolution rate in 0.26 N tetramethylammonium hydroxide at 23° C. of at least 50 Å/sec, wherein said repeat units are present in said acrylic polymer in the following mole % ranges, based on the total moles of all different repeat units present, and further where the summation of the individual mole % values for all repeat units present in said polymer must equal 100 mole %, and

(1) ranges from about 0 to about 35 mole %

(2) ranges from about 5 to about 55 mole %

(3) ranges from about 0 to about 30 mole %

(4) ranges from about 15 to about 55 mole %

(5) ranges from about 10 to about 40 mole %,

(6) ranges from about 0 to about 25 mole %, and

R₁, R₂, R₃, R₄, R₅, and R₆ are individually selected from either H, F, a C-1 to C-4 fluoroalkyl, or a C-1 to C-4 alkyl

R₇ is selected from H, a C-1 to C-4 alkyl, a C-1 to C-4 alkyloxy alkyl, and a halogen,

R₈ is a C-3 to C-8 cyclic alkyl, or a C-7 to C-14 alicyclic alkyl,

R₉ is a C-2 to C-8 (hydroxy)alkylene moiety,

R₁₀ is an acid cleavable group,

R₁₁ is a C-3 to C-12, (alkyloxy)alkylene moiety; and

in said heterocyclic thiol for said structure (7), Xt is selected from the group consisting of C(Rt₁)(Rt₂), O, S, Se, and Te; for said structure (8), Y is selected from the group consisting of C(Rt₃) and N; for said structure (9), Z is selected from the group consisting of C(Rt₃) and N; and

Rt₁, Rt₂, and Rt₃ are independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms;

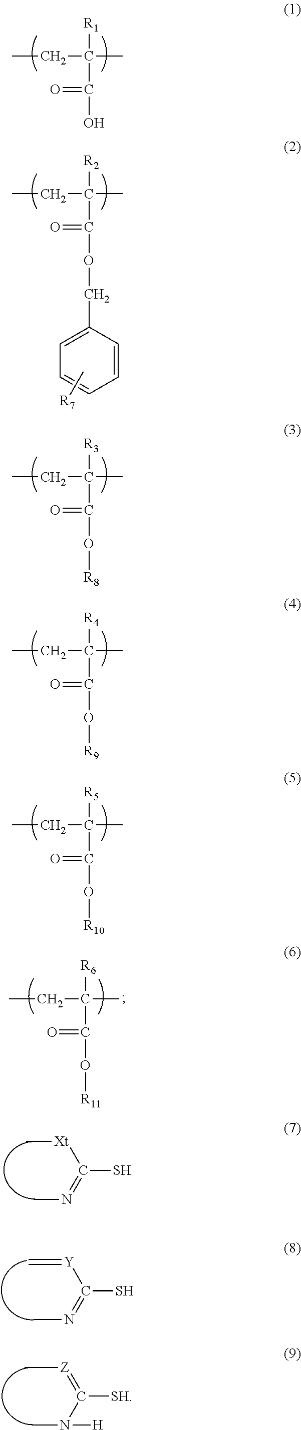

### Diazonaphthoquinonesulfonate Photoactive Compound (DNQ-PAC)

In one aspect of the inventive composition described herein said DNQ-PAC is a single material or a mixture of materials in which a 2,1,5-Diazonaphthoquinonesulfonate moiety having structure (10) forms at least one sulfonate ester with a phenolic compound.

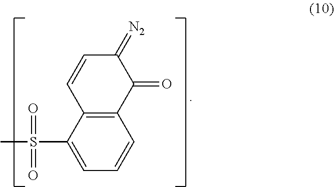

In one aspect of the inventive composition described herein said DNQ PAC is a single material or a mixture of materials having general formula (11) wherein D_{1c}, D_{2c}, D_{3c} and D_{4c} are individually selected from H or a moiety having structure (10), and further wherein at least one of D_{1c}, D_{2c}, D_{3c} or D_{4c} is a moiety having structure (10).

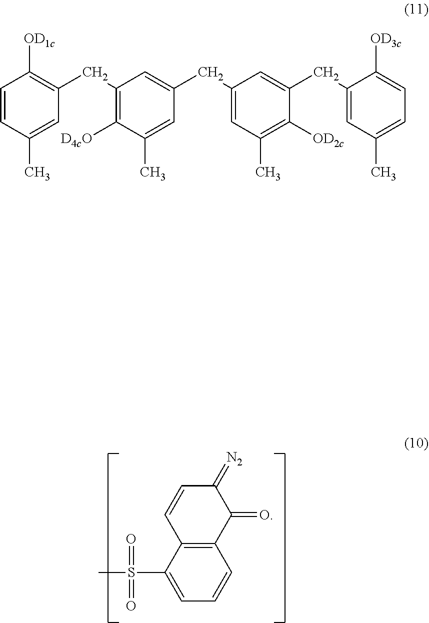

In one aspect of the inventive composition described herein said DNQ PAC is either a single compound or a mixture of PAC compounds having structure (12a), wherein D₁ₑ, D₂ₑ, and D₃ₑ are individually selected from H or a moiety having structure (10), and further wherein at least one of D₁ₑ, D₂ₑ, or D₃ₑ is a moiety having structure (10).

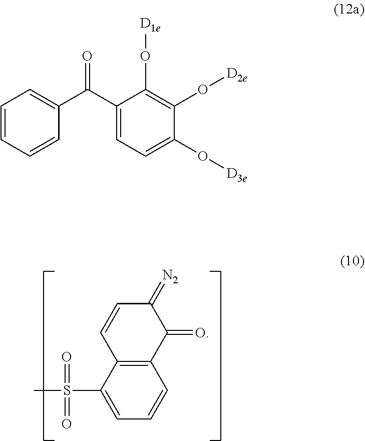

In one aspect of the inventive composition described herein said DNQ PAC is either a single compound or a mixture of PAC compounds having structure (12b), wherein D₁ₑ, D₂ₑ, D₃ₑ and D₄ₑ are individually selected from H or a moiety having structure (10), and further wherein at least one of d₁ₑ, D₂ₑ, D₃ₑ or D₄ₑ is a moiety having structure (10).

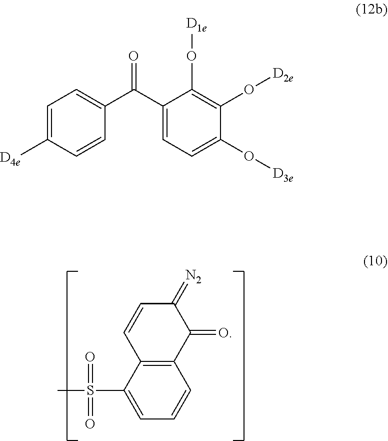

In one aspect of the inventive composition described herein said DNQ PAC is either a single compound or a mixture of compounds having structure (13), wherein D_{1f}, D_{2f}, D_{3f} and D_{4f} are individually selected from H or a moiety having structure (10), and further wherein at least one of D_{1f}, D_{2f}, D_{3f} or D_{4f} is a moiety having structure (10),

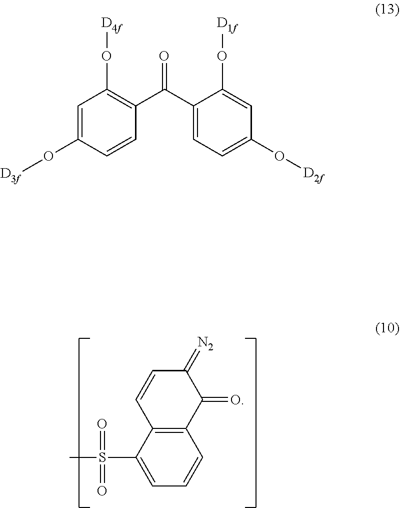

### Photoacid Generator

The photosensitive composition disclosed herein may include a variety of photoacid generators, such as but not limited to onium salts, dicarboximidyl sulfonate esters, oxime sulfonate esters, diazo(sulfonyl methyl) compounds, disulfonyl methylene hydrazine compounds, nitrobenzyl sulfonate esters, biimidazole compounds, diazomethane derivatives, glyoxime derivatives, β-ketosulfone derivatives, disulfone derivatives, sulfonic acid ester derivatives, imidoyl sulfonate derivatives, and halogenated triazine compounds, or combinations thereof.

Onium salt photoacid generators may comprise, without limitation, alkyl sulfonate anions, substituted and unsubstituted aryl sulfonate anions, fluoroalkyl sulfonate anions, fluoarylalkyl sulfonate anions, fluorinated arylalkyl sulfonate anions, hexafluorophosphate anions, hexafluoroarsenate anions, hexafluoroantimonate anions, tetrafluoroborate anions, equivalents thereof or combinations thereof

Specifically, without limitation, suitable photoacid generators may include triphenylsulfonium trifluoromethanesulfonate, triphenylsulfonium nonafluoro-n-butanesulfonate, triphenylsulfonium perfluoro-n-octanesulfonate, and triphenylsulfonium 2-(bicyclo[2.2.1]heptan-2-yl)-1,1,2,2-tetrafluoroethanesulfonate, 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-(bicyclo[2.2.1]heptan-2-yl)-1,1,2,2-tetrafluoroethanesulfonate, 4-methanesulfonylphenyldiphenylsulfonium trifluoromethanesulfonate, 4-methanesulfonylphenyldiphenylsulfonium nonafluoro-n-butanesulfonate, 4-methanesulfonylphenyldiphenylsulfonium perfluoro-n-octanesulfonate, and 4-methanesulfonylphenyldiphenylsulfonium 2-(bicyclo[2.2.1]heptan-2-yl)-1,1,2,2-tetrafluoroethanesulfonate, diphenyliodonium trifluoromethanesulfonate, diphenyliodonium nonafluoro-n-butanesulfonate, diphenyliodonium perfluoro-n-octanesulfonate, diphenyliodonium 2-(bicyclo[2.2.1]heptan-2-yl)-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-(bicyclo[2.2.1]heptan-2-yl)-1,1,2,2-tetrafluoroethanesulfonate, 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-(bicyclo[2.2.1]heptan-2-yl)-1,1,2,2-tetrafluoroethanesulfonate, 1-(6-n-butoxynaphthalen-2-yl)tetrahydrothiophenium trifluoromethanesulfonate, 1-(6-n-butoxynaphthalen-2-yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-(bicyclo[2.2.1]heptan-2-yl)-1,1,2,2-tetrafluoroethanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydrothiophenium 2-(bicyclo[2.2.1]heptan-2-yl)-1,1,2,2-tetrafluoroethanesulfonate N-(trifluoromethanesulfonyloxy)bicyclo[2.2.1]hept-5-ene-2,3-dicarboximide, N-(nonafluoro-n-butanesulfonyloxy)bicyclo[2.2.1]hept-5-ene-2,3-dicarboxyimide, N-(perfluoro-n-octanesulfonyloxy)bicyclo[2.2.1]hept-5-ene-2,3-dicarboxyimide, N-[2-(bicyclo[2.2.1]heptan-2-yl)-1,1,2,2-tetrafluoroethanesulfonyloxy]bicyclo[2.2.1]hept-5-ene-2,3-dicarboxyimide, 1,3-dioxo-1H-benzo[de]isoquinolin-2(3H)-yl trifluoromethanesulfonate(naphthalene dicarboximidyl triflate), N-[2-(tetracyclo[4.4.0.1^{2,5}.1^{7,10}]dodecan-3-yl)-1,1-difluoroethanesulfonyloxy]bicyclo[2.2.1]hept-5-ene-2,3-dicarboxyimide, 1,3-dioxoisoindolin-2-yl trifluoromethanesulfonate, 1,3-dioxoisoindolin-2-yl nonafluoro-n-butane sulfonate, 1,3-dioxoisoindolin-2-yl perfluoro-n-octane sulfonate, 3-dioxoisoindolin-2-yl 2-(bicyclo[2.2.1]heptan-2-yl)-1,1,2,2-tetrafluoroethanesulfonate, 3-dioxoisoindolin-2-yl N-[2-(tetracyclo[4.4.0.1^{2,5}.1^{7,10}]dodecan-3-yl)-1,1-difluoroethanesulfonate, 1,3-dioxo-1H-benzo[de]isoquinolin-2(3H)-yl trifluoromethanesulfonate, 1,3-dioxo-1H-benzo[de]isoquinolin-2(3H)-yl nonafluoro-n-butane sulfonate, 1,3-dioxo-1H-benzo[de]isoquinolin-2(3H)-yl perfluoro-n-octanesulfonate, 1,3-dioxo-1H-benzo[de]isoquinolin-2(3H)-yl 2-(bicyclo[2.2.1]heptan-2-yl)-1,1,2,2-tetrafluoroethanesulfonate, or 1,3-dioxo-1H-benzo[de]isoquinol in-2(3H)-yl N-[2-(tetracyclo[4.4.0.1^{2,5}.1^{7,10}]dodecan-3-yl)-1,1-difluoroethanesulfonate, (E)-2-(4-methoxystyryl)-4,6-bis(trichloromethyl)-1,3,5-triazine, 2-(Methoxyphenyl)-4,6-bis-(trichloromethyl)-s-triazine, 2-[2-(Furan-2-yl)ethenyl]-4,6-bis(trichloromethyl)-s-triazine, 2-[2-(5-methylfuran-2-yl)ethenyl)-4,6-bis(trichloromethyl)-s-triazine, 2-[2-(3,4-Dimethoxyphenyl)ethenyl]-4,6-bis(trichloromethyl)-s-triazine, equivalents thereof or combinations thereof. Suitable photoacid generators may also include onium salts comprising anions and cations in combinations not shown supra.

The photosensitive composition disclosed herein may also comprise photosensitizers that extend the effective wavelength and/or energy range. Such photosensitizers may be, without limitation, substituted and unsubstituted anthracenes, substituted and unsubstituted phenothiazines, substituted and unsubstituted perylenes, substituted and unsubstituted pyrenes, and aromatic carbonyl compounds, such as benzophenone and thioxanthone, fluorene, carbazole, indole, benzocarbazole, acridone chlorpromazine, equivalents thereof or combinations of any of the foregoing.

### Heterocyclic Thiol

It is understood that for said heterocyclic thiols chosen from structures (7), (8) and (9) described above that these structures represent one of potentially several tautomeric forms. For example, without limitation, structures (7) (8) and (9) may occur as their prototropic tautomer, whether in equilibrium or disequilibrated as follows:

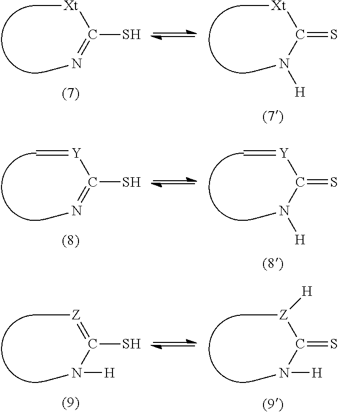

Moreover, interaction with a surface such as a chalcophilic surface or other components in solution may influence the relative concentrations of the ring structures, (7), (8) and (9), and their respective tautomers. Accordingly, it is understood that prototropic tautomers (including annular tautomers) and valence tautomers may be referred to interchangeably by naming any of their tautomeric forms.

In another embodiment wherein said inventive composition comprises at least one heterocyclic thiol chosen from the above general structures (7), (8) or (9) or tautomers thereof such may be chosen without limitation from substituted or unsubstituted triazole thiols, substituted or unsubstituted imidazole thiols, substituted or unsubstituted triazine thiols, substituted or unsubstituted mercapto pyrimidines, substituted or unsubstituted thiadiazole-thiols, substituted or unsubstituted indazole thiols, tautomers thereof or combinations thereof. Substituents may include, without limitation, saturated or unsaturated hydrocarbon groups, substituted or unsubstituted aromatic rings, aliphatic, aromatic or heteroaromatic alcohols, amines, amides, imides carboxylic acids, esters, ethers, halides, and the like. Such substituents may be used in concert with the heterocyclic thiol to improve solubility, to modify interaction with the substrate, to enhance exposure to light or to act as an antihalation dye.

In another embodiment wherein said inventive composition comprises at least one heterocyclic thiol chosen from the above general structures (7), (8) or (9), or tautomers thereof such heterocyclic thiols may be chosen, without limitation, from the following compounds (10 to (17t) in unsubstituted or substituted form:

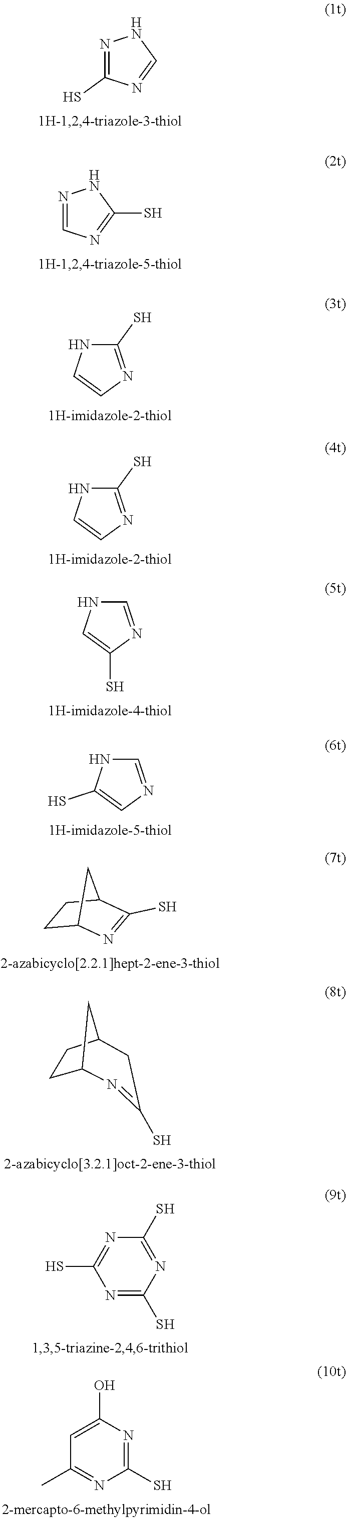

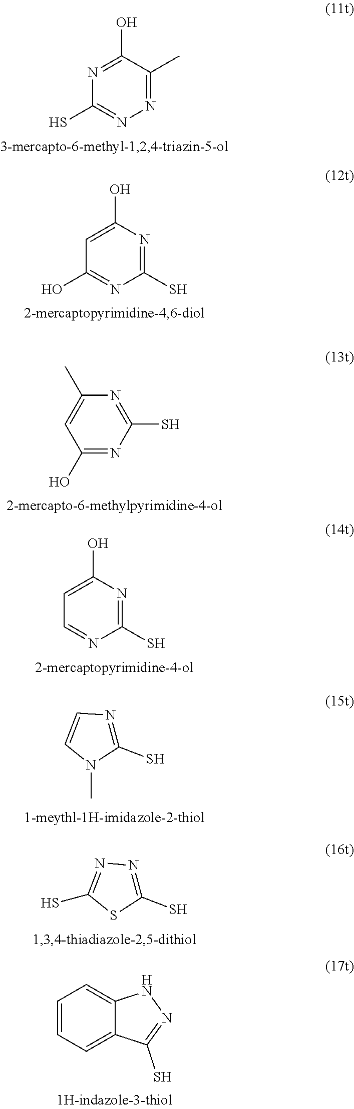

In another embodiment wherein said inventive composition comprises at least one heterocyclic thiol chosen from the above general structures (7), (8) or (9) or tautomers thereof such heterocyclic thiols may be chosen from thiouracil derivatives such as 2-thiouracil. These include, without limitation, 5-methyl-2-thiouracil, 5,6-dimethyl-2-thiouracil, 6-ethyl-5-methyl-2-thiouracil, 6-methyl-5-n-propyl-2-thiouracil, 5-ethyl-2-thioracil, 5-n-propyl-2-thiouracil, 5-n-butyl-2-thiouracil, 5-n-hexyl-2-thiouracil, 5-n-butyl-6-ethyl-2-thiouracil, 5-hydroxy-2-thiouracil, 5,6-dihydroxy-2-thiouracil, 5-hydroxy-6-n-propyl-2-thiouracil, 5-methoxy-2-thiouracil, 5-n-butoxy-2-thiouracil, 5-methoxy-6-n-propyl-2-thiouracil, 5-bromo-2-thiouracil, 5-chloro-2-thiouracil, 5-fluoro-2-thiouracil, 5-amino-2-thiouracil, 5-amino-6-methyl-2-thiouracil, 5-amino-6-phenyl-2-thiouracil, 5,6-diamino-2-thiouracil, 5-allyl-2-thiouracil, 5-allyl-3-ethyl-2-thiouracil, 5-allyl-6-phenyl-2-thiouracil, 5-benzyl-2-thiouracil, 5-benzyl-6-methyl-2-thiouracil, 5-acetamido-2-thiouracil, 6-methyl-5-nitro-2-thiouracil, 6-amino-2-thiouracil, 6-amino-5-methyl-2-thiouracil, 6-amino-5-n-propyl-2-thiouracil, 6-bromo-2-thiouracil, 6-chloro-2-thiouracil, 6-fluoro-2-thiouracil, 6-bromo-5-methyl-2-thiouracil, 6-hydroxy-2-thiouracil, 6-acetamido-2-thiouracil, 6-n-octyl-2-thiouracil, 6-dodecyl-2-thiouracil, 6-tetradodecyl-2-thiouracil, 6-hexadecyl-2-thiouracil, 6-(2-hydroxyethyl)-2-thiouracil, 6-(3-isopropyloctyl)-5-methyl-2-thiouracil, 6-(m-nitrophenyl)-2-thiouracil, 6-(m-nitrophenyl)-5-n-propyl-2-thiouracil, 6-α-naphthyl-2-thiouracil, 6-α-naphthyl-5-t-butyl-2-thiouracil, 6-(p-chlorophenyl)-2-thiouracil, 6-(p-chlorophenyl)-2-ethyl-2-thiouracil, 5-ethyl-6-eicosyl-2-thiouracil, 6-acetamido-5-ethyl-2-thiouracil, 6-eicosyl-5-allyl-2-thiouracil, 5-amino-6-phenyl-2-thiouracil, 5-amino-6-(p-chlorophenyl)-2-thiouracil, 5-methoxy-6-phenyl-2-thiouracil, 5-ethyl-6-(3,3-dimethyloctyl)-2-thiouracil, 6-(2-bromoethyl)-2-thiouracil.

In another embodiment wherein said inventive composition comprises at least one heterocyclic thiol chosen from the above general structures (7), (8) or (9) or tautomers thereof such heterocyclic thiols may be selected from the group consisting of unsubstituted triazole thiol, substituted triazole thiol, unsubstituted imidazole thiol, substituted imidazole thiol, substituted triazine thiol, unsubstituted triazine thiol, a substituted mercapto pyrimidine, unsubstituted mercapto pyrimidine, a substituted thiadiazole-thiol, unsubstituted thiadiazole-thiol, substituted indazole thiol, unsubstituted indazole thiol, tautomers thereof, and combinations thereof

In another embodiment wherein said inventive composition comprises at least one heterocyclic thiol chosen from the above general structures (7), (8) or (9) or tautomers thereof such heterocyclic thiols may be selected from the group consisting of 1,3,5-triazine-2,4,6-trithiol, 2-mercapto-6-methylpyrimidin-4-ol, 3-mercapto-6-methyl-1,2,4-triazin-5-ol, 2-mercaptopyrimidine-4,6-diol, 1H-1,2,4-triazole-3-thiol, 1H-1,2,4-triazole-5-thiol, 1H-imidazole-2-thiol, 1H-imidazole-5-thiol, 1H-imidazole-4-thiol, 2-azabicyclo[3.2.1]oct-2-ene-3-thiol, 2-azabicyclo[2.2.1]hept-2-ene-3-thiol, 1H-benzo[d]imidazole-2-thiol, 2-mercapto-6-methylpyrimidin-4-ol, 2-mercaptopyrimidin-4-ol, 1-methyl-1H-imidazole-2-thiol, 1,3,4-thiadiazole-2,5-dithio1,1H-indazole-3-thiol, tautomers thereof and combinations thereof.

Further disclosed herein is a method of forming a positive relief image comprising: forming a photosensitive layer by applying the positive working photosensitive composition described herein to a substrate; image-wise exposing the photosensitive layer to actinic radiation to form a latent image; and developing the latent image in a developer. Optionally, the image-wise exposed photosensitive layer may be thermally treated, depending on the chemistry of deprotection. Preferably, the substrate comprises a chalcophile. More preferably, the substrate is copper.

The heterocyclic thiols in the photosensitive composition disclosed herein may include, without limitation, substituted or unsubstituted triazole thiols, substituted or unsubstituted imidazole thiols, substituted or unsubstituted triazine thiols, substituted or unsubstituted mercapto pyrimidines, substituted or unsubstituted thiadiazole-thiols, substituted or unsubstituted indazole thiols, tautomers thereof or combinations thereof. Substituents may include, without limitation, saturated or unsaturated hydrocarbon groups, substituted or unsubstituted aromatic rings, aliphatic, aromatic or heteroaromatic alcohols, amines, amides, imides carboxylic acids, esters, ethers, halides, and the like. Such substituents may be used in concert with the heterocyclic thiol to improve solubility, to modify interaction with the substrate, to enhance exposure to light or to act as an antihalation dye.

Such heterocyclic thiols may include, without limitation the following compounds in unsubstituted or substituted form:

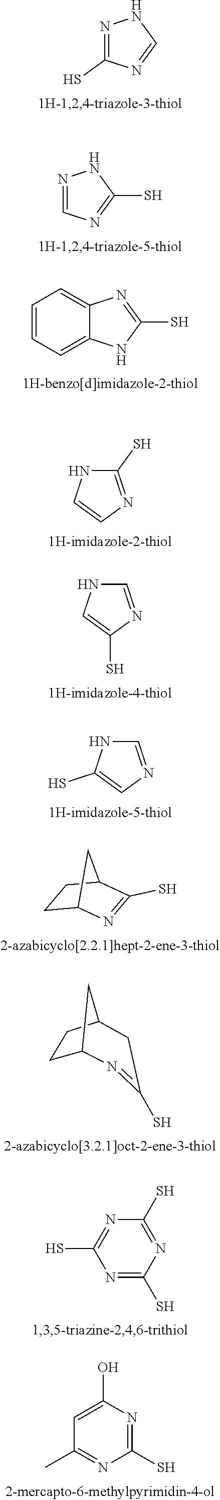

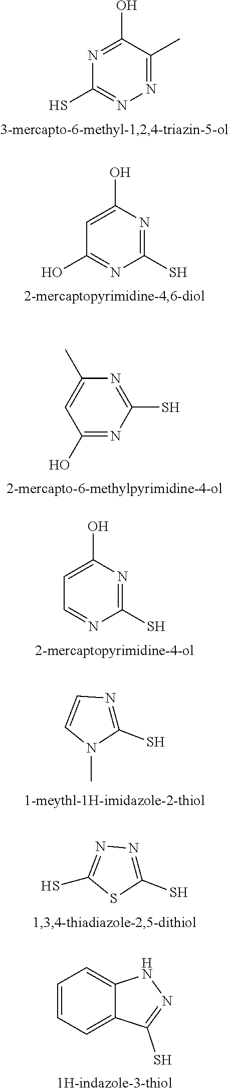

Thiouracil derivatives such as 2-thiouracil are further examples. These include, without limitation, 5-methyl-2-thiouracil, 5,6-dimethyl-2-thiouracil, 6-ethyl-5-methyl-2-thiouracil, 6-methyl-5-n-propyl-2-thiouracil, 5-ethyl-2-thioracil, 5-n-propyl-2-thiouracil, 5-n-butyl-2-thiouracil, 5-n-hexyl-2-thiouracil, 5-n-butyl-6-ethyl-2-thiouracil, 5-hydroxy-2-thiouracil, 5,6-dihydroxy-2-thiouracil, 5-hydroxy-6-n-propyl-2-thiouracil, 5-methoxy-2-thiouracil, 5-n-butoxy-2-thiouracil, 5-methoxy-6-n-propyl-2-thiouracil, 5-bromo-2-thiouracil, 5-chloro-2-thiouracil, 5-fluoro-2-thiouracil, 5-amino-2-thiouracil, 5-amino-6-methyl-2-thiouracil, 5-amino-6-phenyl-2-thiouracil, 5,6-diamino-2-thiouracil, 5-allyl-2-thiouracil, 5-allyl-3-ethyl-2-thiouracil, 5-allyl-6-phenyl-2-thiouracil, 5-benzyl-2-thiouracil, 5-benzyl-6-methyl-2-thiouracil, 5-acetamido-2-thiouracil, 6-methyl-5-nitro-2-thiouracil, 6-amino-2-thiouracil, 6-amino-5-methyl-2-thiouracil, 6-amino-5-n-propyl-2-thiouracil, 6-bromo-2-thiouracil, 6-chloro-2-thiouracil, 6-fluoro-2-thiouracil, 6-bromo-5-methyl-2-thiouracil, 6-hydroxy-2-thiouracil, 6-acetamido-2-thiouracil, 6-n-octyl-2-thiouracil, 6-dodecyl-2-thiouracil, 6-tetradodecyl-2-thiouracil, 6-hexadecyl-2-thiouracil, 6-(2-hydroxyethyl)-2-thiouracil, 6-(3-isopropyloctyl)-5-methyl-2-thiouracil, 6-(m-nitrophenyl)-2-thiouracil, 6-(m-nitrophenyl)-5-n-propyl-2-thiouracil, 6-α-naphthyl-2-thiouracil, 6-α-naphthyl-5-t-butyl-2-thiouracil, 6-(p-chlorophenyl)-2-thiouracil, 6-(p-chlorophenyl)-2-ethyl-2-thiouracil, 5-ethyl-6-eicosyl-2-thiouracil, 6-acetamido-5-ethyl-2-thiouracil, 6-eicosyl-5-allyl-2-thiouracil, 5-amino-6-phenyl-2-thiouracil, 5-amino-6-(p-chlorophenyl)-2-thiouracil, 5-methoxy-6-phenyl-2-thiouracil, 5-ethyl-6-(3,3-dimethyloctyl)-2-thiouracil, 6-(2-bromoethyl)-2-thiouracil.

### Acrylate Polymer

In one aspect of the inventive composition described herein said repeat units of said acrylate polymer are selected from the group consisting of repeat units having structure (1), (2), (3), (4), (5), and (6).

In another aspect of this inventive composition said repeat units of said acrylate polymer are selected from the group consisting of repeat units having structure (1), (2), (4), (5), and (6).

In any of the aspects of the inventive composition described herein said acrylate polymer is one wherein
Structure (1) ranges from about 0 to about 35 mole %,
Structure (2) ranges from about 5 to about 55 mole %,
Structure (3) ranges from about 0 to about 30 mole %,
Structure (4) ranges from about 15 to about 55 mole %,
Structure (5) ranges from about 10 to about 40 mole %, and
Structure (6) ranges from about 0 to about 25 mole %;
In a preferred embodiment, said acrylate polymer is one wherein
Structure (1) ranges from about 5 to about 20 mole %,
Structure (2) ranges from about 5 to about 25 mole %,
Structure (3) ranges from about 0 to about 30 mole %,
Structure (4) ranges from about 15 to about 55 mole %,
Structure (5) ranges from about 20 to about 40 mole %, and
Structure (6) ranges from about 5 to about 25 mole %.

In another aspect of this inventive composition said acrylate polymer is one whose repeat units are the ones having structures (1), (2a), (4a), (5), and (6a) wherein n and n′ are the numbers of methylene spacer moieties and range, independently, from 1 to 4, R₁, R₂, R₄, R₅, and R₇, individually, are selected from a C-1 to C-4 alkyl, R_{9′} and R_{11′} are individually selected from H or a C-1 to C-4 alkyl, and R_{11″}, is a C-1 to C-4 alkyl. In one aspect of this embodiment, structure (1) ranges from about 5 to about 20 mole %, structure (2a) ranges from about 5 to about 25 mole %, structure (4a) ranges from about 15 to about 55 mole %, structure (5) ranges from about 20 to about 40 mole %, and structure (6a) ranges from about 5 to about 25 mole %.

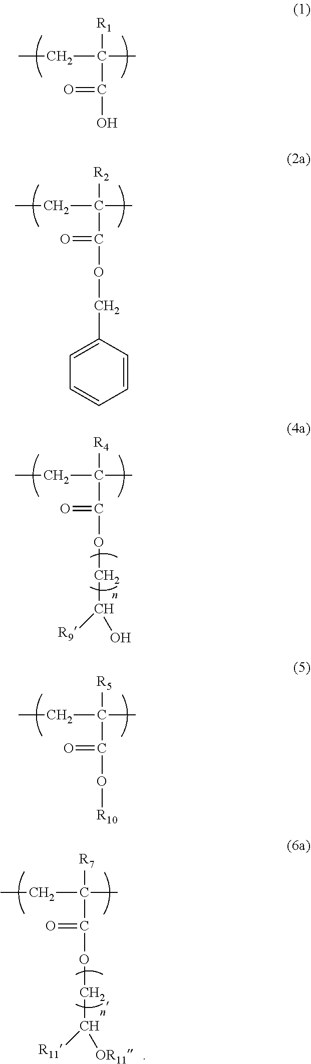

In any of inventive compositions described herein said acrylate polymer component is one wherein for said repeat unit of structure (5), R₁₀ is an acid cleavable group selected from the group consisting of a t-butyl group, a tetrahydropyran-2-yl group, a tetrahydrofuran-2-yl group, a 4-methoxytetrahydropyran-4-yl group, a 1-ethoxyethyl group, a 1-butoxyethyl group, a 1-propoxyethyl group, a 3-oxocyclohexyl group, a 2-methyl-2-adamantyl group, a 2-ethyl-2-adamantyl group, a 8-methyl-8-tricyclo[5.2.1.02,6 ]decyl group, a 1,2,7,7-tetramethyl-2-norbornyl group, a 2-acetoxymenthyl group, a 2-hydroxymethyl group a 1-methyl-1-cyclohexylethyl group, a 4-methyl-2-oxotetrahydro-2H-pyran-4-yl group, a 2,3-dimethylbutan-2-yl group, a 2,3,3-trimethylbutan-2-yl group, a 1-methyl cyclopentyl group, a 1-ethyl cyclopentyl group, a 1-methyl cyclohexyl group, 1-ethyl cyclohexyl group, a 1,2,3,3-tetramethylbicyclo[2.2.1]heptan-2-yl group, a 2-ethyl-1,3,3-trimethylbicyclo[2.2.1]heptan-2-yl group, a 2,6,6-trimethylbicyclo[3.1.1]heptan-2-yl group, a 2,3-dimethylpentan-3-yl group, or a 3-ethyl-2-methylpentan-3-yl group.

In one aspect of the inventive compositions described herein said acrylate polymer is one whose repeat units are the ones having structures (1), (2b), (4b), (5a), and (6b). In another aspect of this embodiment, structure (1a) ranges from about 5 to about 20 mole %, structure (2b) ranges from about 5 to about 25 mole %, structure (4b) ranges from about 15 to about 55 mole %, structure (5a) ranges from about 20 to about 40 mole %, and (6b) ranges from about 5 to about 25 mole %.

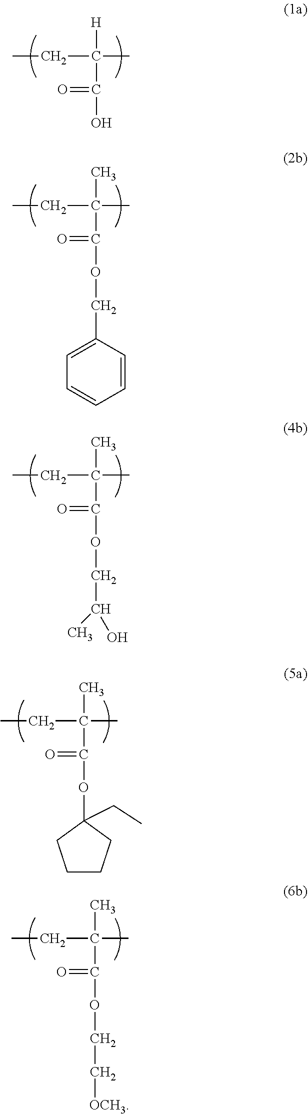

In the embodiments of the inventive composition described herein said acrylic polymer is one comprising repeat units selected from ones having structure (1), (2), (3), (4), (5), and (6), wherein (1) ranges from about 0 to about 35 mole %, (2) ranges from about 5 to about 55 mole %, (3) ranges from about 0 to about 30 mole %, (4) ranges from about 15 to about 55 mole %, (5) ranges from about 10 to about 40 mole %, and (6) ranges from about 0 to about 25 mole %, additionally other types of (meth)acrylic repeat unit and/or styrenic repeat units may be present. In this embodiment, said acrylic polymer may comprise at least one styrenic repeat units selected from the ones having the structure (14), where R₁₄ is chosen from H or CH₃ and R_{14′} and R_{14″} can be the same or different, and are chosen from H, OH, ORₚ, O—(C═O)—ORₚ, or O—(C═O)—(C═O)—ORₚ wherein Rp is an acid labile group having the same scope as described herein for the acid labile group Rio. Preferably, in this embodiment, the polymer comprises at least one styrenic repeat unit selected from the ones having the structure (14), where R₁₄ is chosen from H, or CH₃, and R_{14′} and R_{14″} can be the same or different, and are chosen from H, OH, OCOOC(CH₃)₃, or OCOCOO(CH₃)₃ A specific non limiting Rp is a tertiary alkyl having at least one beta-hydrogen capable of elimination to form an alkene upon acidolytic cleavage by H+ (e.g., tert-butyl). Further, in this embodiment, said acrylic polymer may comprise at least one (meth)acrylate of a lactone moiety which is either a single cyclic lactone, or a lactone moiety comprised within an alicyclic alkyl. Said lactone moiety may be either a single cyclic lactone, or a lactone moiety comprised within an alicyclic alkyl. More specific examples of such (metha)acrylate of a lactone moiety are shown in structure (15), wherein R₁₅ is chosen from H or CH₃ and m is 1 or 2. In one aspect of this embodiment said acrylic polymer additionally comprises both a styrenic repeat unit of structure (1) and (meth)acrylate repeat unit of structure (15).

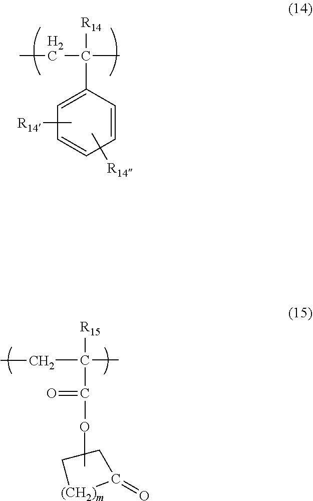

For the inventive composition described herein component d) of said acrylate polymer may, without limitation, have a weight average molecular weight in the range from 800 Daltons to 30,000 Daltons. Further exemplary weight average molecular weights of the structure may, without limitation, range from 1,500 Daltons to 20,000 Daltons. Still further exemplary weight average molecular weights of the structure may, without limitation, range from 2,500 Daltons to 20,000 Daltons. Molecular weight can be determined by gel permeation chromatography using a universal calibration method, calibrated to polystyrene standards.

### Novolak Polymer

Novolak polymers used in the inventive composition described herein may comprise repeat units having bridges and phenolic compounds. Suitable phenolic compounds include, without limitation, phenols, cresols, substituted and unsubstituted resorcinols, xylenols, substituted and unsubstituted benzene triols and combinations thereof. Novolak polymers are produced, usually, with an acid catalyst, by condensation polymerization of phenolic compounds and aldehydes such as formaldehyde, acetaldehyde or substituted or unsubstituted benzaldehydes or condensation products of phenolic compounds and substituted or unsubstituted methylol compounds. Bridges described supra may comprise methylene groups or methyne groups. Novolak polymers can also be made as condensation products of ketones such as acetone, methyl ethyl ketone, acetophenone and the like. Catalysts may include Lewis acids, Brønsted acids, dicationic and tricationic metal ions and the like. For example, without limitation, aluminum chloride, calcium chloride, manganese chloride, oxalic acid, hydrochloric acid, sulfuric acid, methane sulfonic acid trifluoromethane sulfonic acid or combinations comprising any of the foregoing may be used.

Examples of suitable Novolak polymers for use in the inventive composition described herein include those obtained by the condensation reaction between a phenolic compound such as phenol, o-cresol, m-cresol, p-cresol, 2-5-xylenol and the like with an aldehyde compound such as formaldehyde in the presence of an acid or multivalent metal-ion catalyst. An exemplary weight average molecular weight for the alkali-soluble Novolak polymer may be in the range from 1,000 to 30,000 Daltons. A further exemplary weight average molecular weight may be from 1,000 to 20,000 Daltons. A still further exemplary weight average molecular weight may be from 1,500 to 10,000 Daltons. Exemplary bulk dissolution rates for Novolak polymers in 2.38% aqueous tetramethylammonium hydroxide are 10 Å/sec (Angstrom units per second) to 15,000 Å/sec. Further exemplary bulk dissolution rates are 100 Å/sec to 10,000 Å/sec. Still further exemplary bulk dissolution rates are 200 Å/sec to 5,000 Å/sec. A still further exemplary bulk dissolution rate of 1,000 Å/sec may be obtained from a single Novolak polymer or a blend of Novolak polymers, each comprising m-cresol repeat units.

Exemplary cresylic Novolak polymers may comprise, in cresol mole percentage terms, 0%-60% p-cresol, 0%-20% o-cresol, and 0%-80% m-cresol. Further exemplary cresylic Novolak polymers may comprise 0%-50% p-cresol, 0%-20% o-cresol, and 50%-100% m-cresol. Repeat units in Novolak polymers are defined by the composition of the polymer, so that, for example, p-cresol may be introduced by polymerization with an aldehyde or by dimethylol-p-cresol. Moreover, cresylic Novolak polymers may contain other phenolic compounds such as phenol, xylenols, resorcinols, benzene triols and the like. Further, Novolak polymers can be branched or linear and may be blended to achieve a selected repeat unit mole percentage or dissolution rate. Bulk dissolution rates may be measured by the following procedure:

(1) A 1-3 μm (micrometer) film of the Novolak resin is spin-coated from a solution on a silicon wafer and soft baked at about 110° C. for about 120 seconds on a contact hot plate.

(2) The film thickness is measured using an optical method such as interferometry or ellipsometry or a mechanical profilometer.

(3) The coated wafer is immersed in a solution of tetramethylammonium hydroxide (TMAH) developer and the time to dissolve completely the Novolak film (t_{c}) is detected visually or by means of optical interferometry (for example, a dissolution rate monitor). The bulk dissolution rate is calculated dividing the film thickness by t_{c}.

In embodiments of the inventive composition described herein said Novolak polymer may be one which comprises a repeat unit of structure (16), wherein, Ra, and Rb are independently a C-1 to C-4 alkyl, na is 0 to 3, nb is 0 or 1.

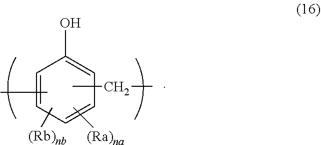

In embodiments of the inventive composition described herein said Novolak polymer may be one which comprises a repeat unit of structure (17), wherein, Rc, is a C-1 to C-4 alkyl, Rd is a C-1 to C-4 alkyl, X is —O—, C(CH₃)₂—, —(C═O)— or —SO₂—, nc is 0 to 3 rid is 0 or 1.

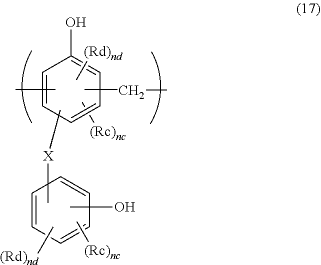

In the embodiments of the inventive composition described herein said Novolak polymer may be one which comprises said Novolak resin comprising said repeat units (16) and (17).

In embodiments of the inventive composition described herein said Novolak polymer may be one which comprises said Novolak resin comprising said repeat units (16) and (17).

In a specific embodiment of the inventive composition described herein said Novolak polymer is a m-cresol and formaldehyde Novolak resin.

In any of the embodiments of the inventive composition described herein the Novolak polymer comprises from about 10 to about 90 wt % solids. Another aspect of this embodiment comprises from about 30 to about 75 wt % solids. As a still further example and without limitation, said Novolak polymer may comprise from 40 wt % solids to about 65 wt % solids.

In still another embodiment, the inventive composition may have at total wt % solids content from about 30 wt % solids to about 65 wt % solids and may be used to form coating which have of 5-200 μm.

### Solvent Component

The photosensitive composition disclosed herein may be dissolved in an organic solvent. Examples of suitable organic solvents include, without limitation, butyl acetate, amyl acetate, cyclohexyl acetate, 3-methoxybutyl acetate, methyl ethyl ketone, methyl amyl ketone, cyclohexanone, cyclopentanone, ethyl-3-ethoxy propanoate, methyl-3-ethoxy propanoate, methyl-3-methoxy propanoate, methyl acetoacetate, ethyl acetoacetate, diacetone alcohol, methyl pivalate, ethyl pivalate, propylene glycol monomethyl ether, propylene glycol monoethyl ether, propylene glycol monomethyl ether propanoate, propylene glycol monoethyl ether propanoate, ethylene glycol monomethyl ether, ethylene glycol monoethyl ether, diethylene glycol monomethyl ether, diethylene glycol monoethyl ether, 3-methyl-3-methoxybutanol, N-methylpyrrolidone, dimethyl sulfoxide, gamma-butyrolactone, propylene glycol methyl ether acetate, propylene glycol ethyl ether acetate, propylene glycol propyl ether acetate, methyl lactate, ethyl lactate, propyl lactate, tetramethylene sulfone, propylene glycol dimethyl ether, dipropylene glycol dimethyl ether, ethylene glycol dimethyl ether or diethylene glycol dimethyl ether, gamma butyrolactone. These solvents may be used singly or in a mixture of two or more.

### Optional Components

Other optional additives, which have compatibility with and can be added to the composition disclosed and claimed herein according to need, include auxiliary resins, plasticizers, surface leveling agents and stabilizers to improve the properties of the resist layer, coloring agents to increase the visibility of the patterned resist layer formed by development, antihalation dyes, and quenchers.

### Quenchers

In one embodiment of the inventive composition described herein it further comprises a quencher which may be selected from a tetraalkylammonium salt, or an amino based quencher having a boiling point of at least 100° C.

Examples of suitable tetraalkylammonium salts are those of carboxylic acids and alkylsulfonic acids. More specifically tetraalkylammonium salts of alkyls dicarboxylic acid may be employed such as the non-limiting example of tetrabutylammonium oxalate and the like.

In another embodiment of any of the above aspects of this invention said amino based quencher having a boiling point of at least 100° C. at 1 atmosphere pressure, is only of a compound or a mixture of compounds having structure (18), is one wherein Rₐₘ₁ is a C-15 to C-20 alkyl moiety, and Rₐₘ₁ₐ is a is —(CH₂)ₙOH, wherein n is an integer ranging from 2 to 4, and further wherein position 3 and 2 are connected by a single bond. In another aspect of this embodiment said amino based quencher has a boiling point of at least 150° C., in another at least 200° C., in another at least 250° C. and in yet another embodiment at least 300° C.

In another embodiment of any of the above aspects of this invention said amino based quencher has a boiling point of at least 100° C. at 1 atmosphere pressure, consists only of a compound or a mixture of compounds having structure (18), having one compound of structure (18), wherein Rₐₘ₁ₐ is —(CH₂)ₙOH, and wherein n is 2 or 3, and further wherein position 3 and 2 are connected by a single bond. In another aspect of this embodiment the quencher has a boiling point of at least 150° C., in another at least 200° C., in another at least 250° C. and in yet another embodiment at least 300° C.

In another embodiment of any of the above aspects of this invention said amino based quencher has a boiling point of at least 100° C. at 1 atmosphere pressure, consists only of a compound or a mixture of compounds having structure (18), wherein Rₐₘ₁ₐ is a is —(CH₂)ₙOH, and wherein n is 2, and further wherein position 3 and 2 are connected by a single bond. In another aspect of this embodiment said amino based quencher has a boiling point of at least 150° C., in another at least 200° C., in another at least 250° C. and in yet another embodiment at least 300° C.

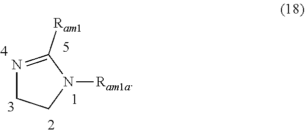

In another embodiment of any of the above aspects of this invention amino based quencher consists of a compound of structure (19).

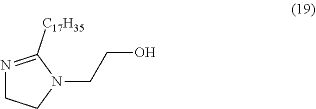

In another embodiment of this invention said amino based quencher has boiling point of at least 100° C. at 1 atmosphere pressure, and is a compound or a mixture of compounds having structure (18), wherein Rₐₘ₁ is a C-15 to C-20 alkyl moiety, and Rₐₘ₁ₐ is a C-1 to C-5 alkyl, and further wherein position 3 and 2 are connected by a single bond. In another aspect of this embodiment the quencher has a boiling point of at least 150° C., in another at least 200° C., in another at least 250° C. and in yet another embodiment at least 300° C.

In another embodiment of this invention said amino based quencher is a compound or a mixture of compounds having structure (18), having a boiling point of at least 100° C. at 1 atmosphere pressure, wherein Rₐₘ₁ is a C-15 to C-20 alkyl moiety, and Rₐₘ₁ₐ is a C-3 to C-5 alkyl, and further wherein position 3 and 2 are connected by a single bond. In another aspect of this embodiment the quencher has a boiling point of at least 150° C., in another at least 200° C., in another at least 250° C. and in yet another embodiment at least 300° C.

In another embodiment of this invention said amino based quencher a boiling point of at least 100° C. at 1 atmosphere pressure, and is a compound or a mixture of compounds having structure (18), wherein Rₐₘ₁ is a C15 to C-20 alkyl moiety, and Rₐₘ₁ₐ is a is a C-4 to C-5 alkyl, and further wherein position 3 and 2 are connected by a single bond. In another aspect of this embodiment the quencher has a boiling point of at least 150° C., in another at least 200° C., in another at least 250° C. and in yet another embodiment at least 300° C.

In another embodiment of any of the above aspects of this said amino based quencher has a boiling point of at least 100° C. at 1 atmosphere pressure, and is compound or a mixture of compounds having structure (18), wherein Rₐₘ₁ is a C-1 to C-5 alkyl moiety, or H and Rₐₘ₁ₐ is —(CH₂)ₙO H, wherein n is an integer ranging from 2 to 4, and further wherein position 3 and 2 are connected by a double bond. In another aspect of this embodiment the quencher has a boiling point of at least 150° C., in another at least 200° C., in another at least 250° C. and in yet another embodiment at least 300° C.

In another embodiment of any of the above aspects of this invention said amino based quencher has a boiling point of at least 100° C. at 1 atmosphere pressure, and is a compound or a mixture of compounds having structure (18), wherein Rₐₘ₁ is a C-1 to C-3 alkyl moiety, or H and Rₐₘ₁ₐ is —(CH₂)ₙOH, wherein n is an integer ranging from 2 to 4, and further wherein position 3 and 2 are connected by a double bond. In another aspect of this embodiment the quencher has a boiling point of at least 150° C., in another at least 200° C., in another at least 250° C. and in yet another embodiment at least 300° C.

In another embodiment of any of the above aspects of this invention said amino based quencher has boiling point of at least 100° C. at 1 atmosphere pressure, and is a compound or a mixture of compounds having structure (18), wherein Rₐₘ₁ is H and Rₐₘ₁ₐ is —(CH2)ₙOH, wherein n is an integer ranging from 2 to 4, and further wherein position 3 and 2 are connected by a double bond. In another aspect of this embodiment the quencher has a boiling point of at least 150° C., in another at least 200° C., in another at least 250° C. and in yet another embodiment at least 300° C.

In another embodiment of any of the above aspects of this invention said amino based quencher is a compound of structure (20).

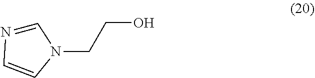

In another embodiment of the above aspects of this invention said amino based quencher is a compound of structure (18), wherein Rₐₘ₁ is a C-15 to C-20 alkyl moiety, and Rₐₘ₁ₐ is a is a C-3 to C-5 alkyl, and further wherein position 3 and 2 are connected by a double bond. In another aspect of this embodiment the quencher has a boiling point of at least 150° C., in another at least 200° C., in another at least 250° C. and in yet another embodiment at least 300° C.

In another embodiment of the above aspects of this invention said amino based quencher is a compound of structure (18), wherein Rₐₘ₁ is a C-15 to C-20 alkyl moiety, and Rₐₘ₁ₐ is a is a C-4 to C-5 alkyl, and further wherein position 3 and 2 are connected by a double bond. In another aspect of this embodiment the quencher has a boiling point of at least 150° C., in another at least 200° C., in another at least 250° C. and in yet another embodiment at least 300° C.

In another embodiment of any of the above aspects of this invention, said amino based quencher, is a compound or a mixture of compounds, having a boiling point of at least 100° C. at 1 atmosphere pressure, having structure (21), where n and n′ are independently an integer ranging from 2 to 4 and R′ is a C-1-C-4 alkyl or H. In another aspect of this embodiment the quencher has a boiling point of at least 150° C., in another at least 200° C., another at least, 250° C. and in yet another embodiment at least 300° C.

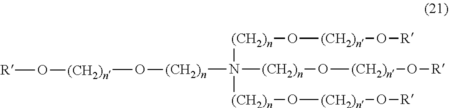

In another embodiment of any of the above aspects of this invention, said amino based quencher, is a compound or a mixture of compounds having structure (21), where n and n′ are 2 and R′ is a C-1-C-4 alkyl or H. In another aspect of this embodiment the quencher has a boiling point of at least 150° C., in another at least 200° C., another at least, 250° C. and in yet another embodiment at least 300° C.

In another embodiment of any of the above aspects of this invention, said amino based quencher, is a compound or a mixture of compounds having structure (21), where n and n′ are 2 and R′ is a C-1-C-4 alkyl or H. In another aspect of this embodiment the quencher has a boiling point of at least 150° C., in another at least 200° C., in another at least 250° C. and in yet another embodiment at least 300° C.

In another embodiment of any of the above aspects of this invention said amino based quencher is only a compound having structure (22).

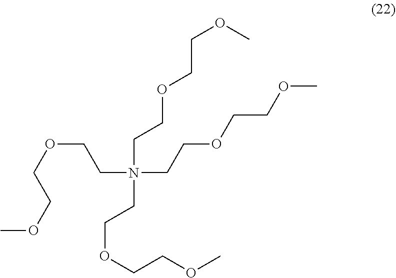

In another embodiment of any of the above aspects of this invention said amino based quencher is a compound or a mixture of compounds, having a boiling point of at least 100° C. at 1 atmosphere pressure, having structure (23), where n and n′ are independently 2 to 4.

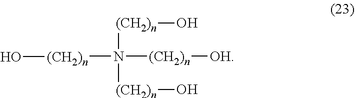

In another embodiment of any of the above aspects of this invention said amino based quencher is a compound having structure (24).

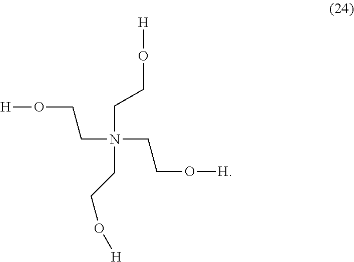

In another embodiment of any of the above aspects of this invention said amino based quencher is a compound or a mixture of compounds, having a boiling point of at least 100° C. at 1 atmosphere pressure, having structure (25), wherein Rₐₘ₃ and Rₐₘ₃ₐ are independently selected from H, or a C-2-C-25 alkyl and further wherein at least one of Rₐₘ₃ or Raₘ₃ₐ is a C-2-C-25 alkyl.

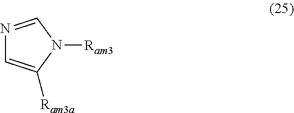

In another embodiment of any of the above aspects of this invention said amino based quencher consists only of a compound or a mixture of compounds, having a boiling point of at least 100° C. at 1 atmosphere pressure, having structure (26), wherein Rₐₘ₄ is a C-2-C-25 alkyl.

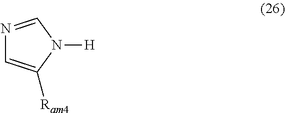

In another embodiment of the above aspects of this invention said based quencher is a compound of structure (18), wherein Rₐₘ₁ is a C2 to C20 alkyl moiety, and Rₐₘ₁ₐ is a C-1 to C-5 alkyl, and further wherein position 3 and 2 are connected by a double bond.

In another embodiment of any of the above aspects of this invention said amino based quencher consists is a compound having structure (27).

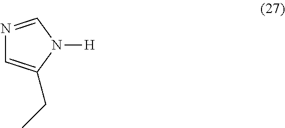

### Surfactants and Surface Leveling Agents

Surface leveling agents may include surfactants. There is no particular restriction with regard to the surfactant, and the examples of it include a polyoxyethylene alkyl ether such as polyoxyethylene lauryl ether, polyoxyethylene stearyl ether, polyoxyethylene cetyl ether, and polyoxyethylene olein ether; a polyoxyethylene alkylaryl ether such as polyoxyethylene octylphenol ether and polyoxyethylene nonylphenol ether; a polyoxyethylene polyoxypropylene block copolymer; a sorbitane fatty acid ester such as sorbitane monolaurate, sorbitane monovalmitate, and sorbitane monostearate; a nonionic surfactant of a polyoxyethylene sorbitane fatty acid ester such as polyoxyethylene sorbitane monolaurate, polyoxyethylene sorbitane monopalmitate, polyoxyethylene sorbitane monostearate, polyethylene sorbitane trioleate, and polyoxyethylene sorbitane tristearate; a fluorinated surfactant such as F-Top EF301, EF303, and EF352 (manufactured by Jemco Inc.), Megafac F171, F172, F173, R08, R30, R90, and R94 (manufactured by Dainippon Ink & Chemicals, Inc.), Florad FC-430, FC-431, FC-4430, and FC-4432 (manufactured by Sumitomo 3M Ltd.), Asahi Guard AG710, Surflon S-381, S-382, S-386, SC101, SC102, SC103, SC104, SC105, SC106, Surfinol E1004, KH-10, KH-20, KH-30, and KH-40 (manufactured by Asahi Glass Co., Ltd.); an organosiloxane polymer such as KP-341, X-70-092, and X-70-093 (manufactured by Shin-Etsu Chemical Co., Ltd.); and an acrylic acid or a methacrylic acid polymer such as Polyflow No. 75 and No. 95 (manufactured by Kyoeisha Yushikagaku Kogyo K. K.).

### Processing

The procedure for the preparation of a patterned photoresist layer by using the photosensitive composition disclosed herein can be conventional. For example, a substrate such as a semiconductor silicon wafer or one with a metal coating as described previously, is evenly coated with the photosensitive composition in the form of a solution by using a suitable coating machine such as a spin-coater followed by baking in a convection oven or on a hotplate to form a photoresist layer which is then exposed pattern-wise to actinic radiation, such as deep ultraviolet light, near ultraviolet light, or visible light emitted from low-pressure, high-pressure and ultra-high-pressure mercury lamps, arc lamps, xenon lamps, ArF, KrF and F₂ excimer lasers, electron beams, x-rays, extreme UV sources, and the like through a photomask or a from a reflective mask bearing a desired pattern on an exposure apparatus and electron beams scanned in accordance with a desired pattern to build up a latent image of the pattern in the resist layer. The actinic radiation may range from 250 nm to 436 nm. Thereafter, the latent image in the photoresist layer may optionally be baked in a convection oven or on a hotplate, developed using an alkaline developer solution such as an aqueous solution of tetra (C₁-C₄ alkyl)ammonium hydroxide, choline hydroxide, lithium hydroxide, sodium hydroxide, or potassium hydroxide, for example, tetramethyl ammonium hydroxide, in a concentration of 1 to 10% w/w, to yield a patterned photoresist layer having good fidelity to the pattern of the photomask.

Thicknesses may range from 20 nm to 100 microns. To achieve these thicknesses, a combination of different spin speeds and total solids concentrations may be employed. Depending on the size of the substrate, spin speeds of from 500 rpm to 10,000 rpm may be used. Concentration may be expressed as a wt % of total solid components in the total weight of the formulation including the solids and the solvents. Without limitation, an exemplary wt % is from about 0.05 wt % to about 65 wt % of the solid component in the formulation. Without limitation, this wt % of solid components in the total formulation may range from about 20 wt % to about 60 wt %. Without limitation, a further exemplary of this wt % range for the formulation is from about 40 wt % to about 60 wt % solids.

The photosensitive composition comprises one or more polymers, one or more photoacid generators, one or more solvents and one or more heterocyclic thiol additives shown supra. The photosensitive composition may further contain a solvent and optional component such as a quencher and a surfactant.

As noted supra., given as wt % solids, for example, the polymers (Novolak+Acrylate Polymer) may be present at from 30 wt % solids to 99 wt % solids, alternatively, polymers may be present at from about 40 wt % solids to about 99 wt % solids. More specifically, while keeping the total wt % solids of polymer as the described above, the Novolak polymer may be present from about 30 wt % solids to about 99 wt % solids, while the acrylate polymer may be present from about 5 wt % solids to about 50 wt % solids. In a more specific aspect, the Novolak polymer may range from about 55 wt % solids to about 99 wt % solids, while the acrylate polymer may range from about 10 wt % solids to about 40 wt % solids.

DNQ-PAC may be present from about 0.2 wt % solids to about 20 wt % solids, alternatively this component may be present from about 0.5 wt % solids to about 10 wt % solids,

Photoacid generators (PAG) may be present from about 0.2 wt % solids to 2 wt % solids, alternatively from about 0.55 wt % solids to about 2 wt % solids.

Heterocyclic thiol additives may be present from about 0.01wt % solids to about 1 wt % solids.

When present, the optional quencher component may be present from about 0.01 to 0.1 wt % solids.

When present, the optional surfactant component may be present from about 0.01 to 0.1 wt % solids.

Each of the documents referred to above is incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### Experimental

### Chemicals

NIT PAG, N-hydroxynaphthalimide triflate is sold under the name (NIT PAG, 100%, Tech, pdr) by Heraeus PM NA Daychem LLC. APS-437 is a surfactant: from Shinetsu, (Tokyo, Japan).

MTA: additive, (1H-1,2,4-triazole-3-thiol); TEA: (Triethylamine); PGME (1-Methoxy-2-propanol); PGMEA (1-Methoxy-2-propanyl acetate), and any other chemical, unless otherwise indicated, were purchased from Sigma Aldrich subsidiary of Merck KGaA (Darmstadt, Germany).

Tetrabutylammonium oxalate was obtained by neutralizing oxalic acid with 25 wt % TMAH in an aqueous solution and removing the water by evaporation.

### Novolak Polymers

For the following formulation examples, three Novolak polymers were used: Novolak-1 is a m-cresol and formaldehyde Novolak and was obtained from Allnex (Alpharetta, Ga.) under the name “ALNOVOL™ SPN 560/47MPAC slow,” Mw 24010, D: 7.3 and had a bulk dissolution rate in 0.26 N aqueous TMAH developer of 700 Å/sec. Novolak-2 is a m-cresol and formaldehyde Novolak and was obtained from Allnex (Alpharetta, Ga.) under the name “ALNOVOL™ SPN 560/47MPAC fast,” Mw 7,245, D: 4.8 and had a bulk dissolution rate in 0.26 N aqueous TMAH developer of 1,600 Å/sec. Novolak-3 is a 1/1 wt/wt blend of Novolak-1 and Novolak-2, with a bulk dissolution rate in 0.26 N aqueous TMAH developer of 1,000 Å/sec. Novolak CL23 is a Novolak polymer (sold under the name CL23F10G by Asahi Yukizai Corporation) that includes 50% m-cresol, 20% p-cresol an 30% 2,5-xylenols, formaldehyde with a M_{w}=4,000 and a dissolution rate of 157.5 Å/sec in 0.26 N aqueous TMAH.

### DNQ-PAC

PW-898 (CAS 107761-81-9) is a 2,2′-4,4-tetrahydroxy-DNQ PAC (6-diazo-5,6-dihydro-5-oxo-1-naphthalene-sulfonic acid ester with (4-hydroxyphenyl)-(2,3,4-trihydroxyphenyl), methanone) available from Accel Pharmtech LLC (East Brunswick, N.J.). It is a mixture of materials having general formula (12), wherein D₁ₑ, D₂ₑ, D₃ₑ, or ate are individually selected from H or a moiety having structure (10), and further wherein at least one of D₁ₑ, D₂ₑ, D₃ₑ, or D₄ₑ is a moiety having structure (10).

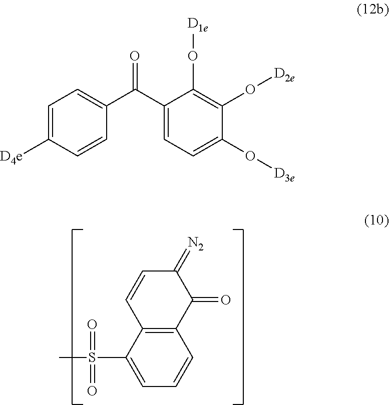

NK-280 is a DNQ-PAC sold under this name by TOYO GOSEI., LTD. It is a mixture of materials having general formula (11) wherein D_{1c}, D_{2c}, D_{3c} and D_{4c} are individually selected from H or a moiety having structure (10), where at least one of D_{1c}, D_{2c}, D_{3c}, or D_{4c} is a moiety having structure (10) and on average about 2.8 of the phenolic positions D_{1c}, D_{2c}, D_{3c} and D_{4c} groups are esterified with (10).

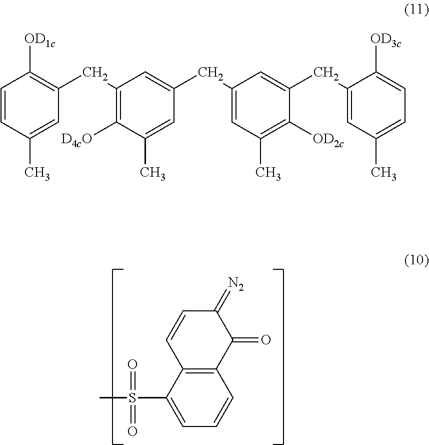

### Acrylic Polymer Synthesis Example 1

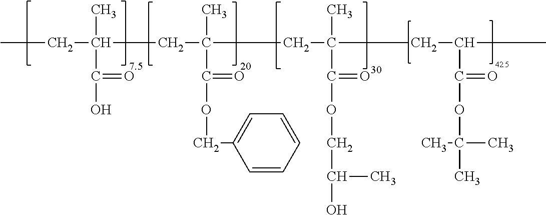

Monomer repeat unit percentages are given as mole percentages. In this example, 6.46 g of methacrylic acid, 35.24 g of benzyl methacrylate, 43.25 g of hydroxypropyl methacrylate, 54.47 g of tert-butyl acrylate are mixed in 209.1 g of PGME solvent. The polymerization reaction proceeds in the presence of 2.3 g of AIBN at 90° C., under nitrogen for 18 hours. After cooling down to room temperature, the reaction mixture is precipitated in DI water. The polymer solid is washed and dried under vacuum at 45° C., yielding 137.1 g (98% yield) with a weight average molecular weight of 15,072 Daltons.

### Acrylic Polymer Synthesis Example 2

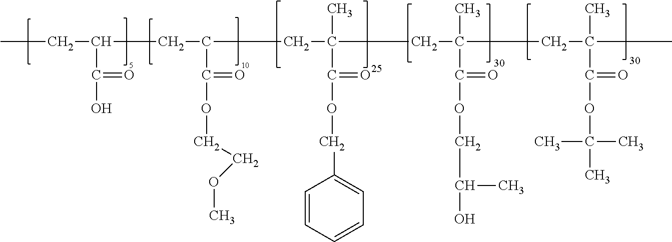

1.8 g of acrylic acid, 6.5 g of methoxyethyl acylate, 22.0 g of benzyl methacrylate, 21.6 g of hydroxypropyl methacrylate, 21.3 g of tert-butyl methacrylate were mixed in 179.6 g of PGME solvent. The polymerization reaction proceeded in the presence of 3.3 g of AIBN at 80° C., under nitrogen for 18 hours. After cooling down to room temperature, the reaction mixture was precipitated in DI water. The white polymer solid was washed and dried under vacuum at 45° C., yielding 73.5 g (>99% yield) with a weight average molecular weight of 11,868 Daltons.

### Acrylic Polymer Synthesis Example 3

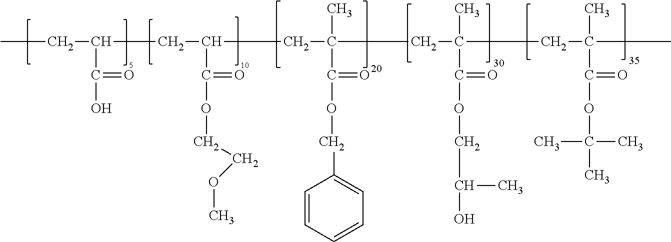

1.8 g of acrylic acid, 6.5g of methoxyethyl acylate, 17.6 g of benzyl methacrylate, 21.6 g of hydroxypropyl methacrylate, 24.9 g of tert-butyl methacrylate were mixed in 172.9 g of PGME solvent. The polymerization reaction proceeded in the presence of 1.6 g of AIBN at 90° C., under nitrogen for 18 hours. After cooling down to room temperature, the reaction mixture was precipitated in DI water. The white polymer solid was washed and dried under vacuum at 45° C., yielding 71.6 g (99% yield) with a weight average molecular weight of 17,205 Daltons.

### Acrylic Polymer Synthesis Example 4

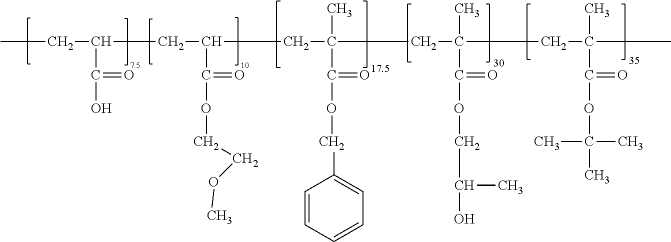

2.7 g of acrylic acid, 6.5 g of methoxyethyl acylate, 15.4 g of benzyl methacrylate, 21.6 g of hydroxypropyl methacrylate, 24.9 g of tert-butyl methacrylate were mixed in 135.2 g of PGME solvent. The polymerization reaction proceeded in the presence of 1.6 g of AIBN at 90° C., under nitrogen for 18 hours. After cooling down to room temperature, the reaction mixture was precipitated in DI water. The white polymer solid was washed and dried under vacuum at 45° C., yielding70.3 g (99% yield) with a weight average molecular weight of 17,153 Daltons.

### Acrylic Polymer Synthesis Example 5

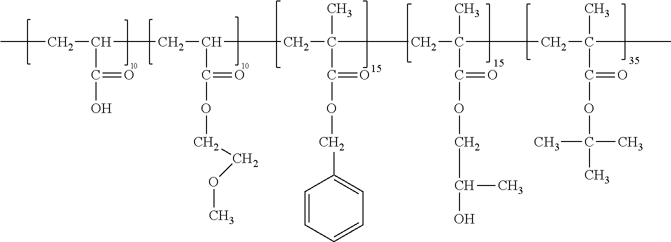

3.6 g of acrylic acid, 6.5 g of methoxyethyl acylate, 13.2 g of benzyl methacrylate, 21.6 g of hydroxypropyl methacrylate, 24.9 g of tert-butyl methacrylate were mixed in 135.8 g of PGME solvent. The polymerization reaction proceeded in the presence of 3.3 g of AIBN at 90° C., under nitrogen for 18 hours. After cooling down to room temperature, the reaction mixture was precipitated in DI water. The white polymer solid was washed and dried under vacuum at 45° C., yielding70.8 g (>99% yield) with a weight average molecular weight of 11,913 Daltons.

### Acrylic Polymer Synthesis Example 6

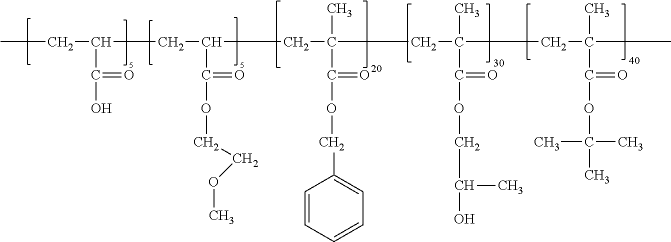

1.8 g of acrylic acid, 3.3 g of methoxyethyl acylate, 17.6 g of benzyl methacrylate, 21.6 g of hydroxypropyl methacrylate, 28.4 g of tert-butyl methacrylate were mixed in 138.2 g of PGME solvent. The polymerization reaction proceeded in the presence of 1.6 g of AIBN at 90° C., under nitrogen for 18 hours. After cooling down to room temperature, the reaction mixture was precipitated in DI water. The white polymer solid was washed and dried under vacuum at 45° C., yielding 71.9 g (99% yield) with a weight average molecular weight of 15,843 Daltons.

### Acrylic Polymer Synthesis Example 7

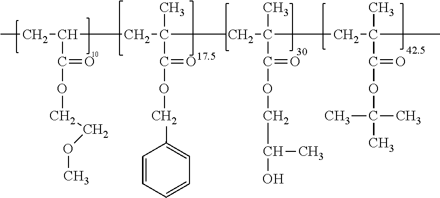

6.5 g of methoxyethyl acylate, 15.4 g of benzyl methacrylate, 21.6 g of hydroxypropyl methacrylate, 30.2 g of tert-butyl methacrylate were mixed in 140.0 g of PGME solvent. The polymerization reaction proceeded in the presence of 1.6 g of AIBN at 90° C., under nitrogen for 18 hours. After cooling down to room temperature, the reaction mixture was precipitated in DI water. The white polymer solid was washed and dried under vacuum at 45° C., yielding 72.45 g (98% yield) with a weight average molecular weight of 17,525 Daltons.

### Acrylic Polymer Synthesis Example 8

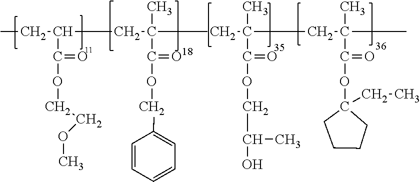

Monomer repeat unit percentages are given as mole percentages. In this example, 7.16 g of methoxyethyl acylate, 15.86 g of benzyl methacrylate, 25.23 g of hydroxypropyl methacrylate, 32.78 g of 1-ethylcyclopentyl methacrylate are mixed in 152.6 g of PGME solvent. The polymerization reaction proceeds in the presence of 1.2 g of AIBN at 90° C., under nitrogen for 18 hours. After cooling down to room temperature, the reaction mixture is precipitated in DI water. The polymer solid is washed and dried under vacuum at 45° C., yielding 79.3 g (98% yield) with a weight average molecular weight of 17,888 Daltons.

### Acrylic Polymer Synthesis Example 9

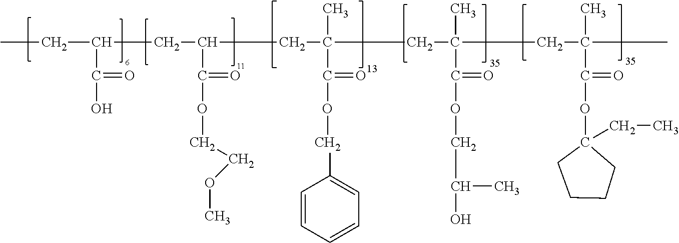

4.32 g of acrylic acid, 14.32 g of methoxyethyl acylate, 22.91 g of benzyl methacrylate, 50.46 g of hydroxypropyl methacrylate, 63.75 g of 1-ethylcyclopentyl methacrylate are mixed in 158.5 g of PGME solvent. The polymerization reaction proceeds in the presence of 2.71 g of AIBN at 90° C., under nitrogen for 18 hours. After cooling down to room temperature, the reaction mixture is precipitated in DI water. The polymer solid is washed and dried under vacuum at 45° C., yielding 153.45 g (98.5% yield) with a weight average molecular weight of 17,103 Daltons.

### Acrylic Polymer Synthesis Example 10

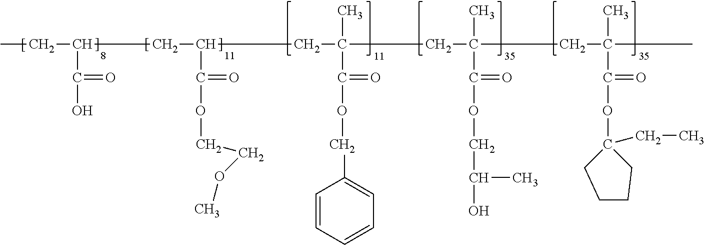

5.76 g of acrylic acid, 14.32 g of methoxyethyl acylate, 19.38 g of benzyl methacrylate, 50.46 g of hydroxypropyl methacrylate, 63.75 g of 1-ethylcyclopentyl methacrylate are mixed in 156.4 g of PGME solvent. The polymerization reaction proceeds in the presence of 2.71 g of AIBN at 90° C., under nitrogen for 18 hours. After cooling down to room temperature, the reaction mixture is precipitated in DI water. The polymer solid is washed and dried under vacuum at 45° C., yielding 150.2 g (97.7% yield) with a weight average molecular weight of 15,557 Daltons.

### Acrylic Polymer Synthesis Example 11

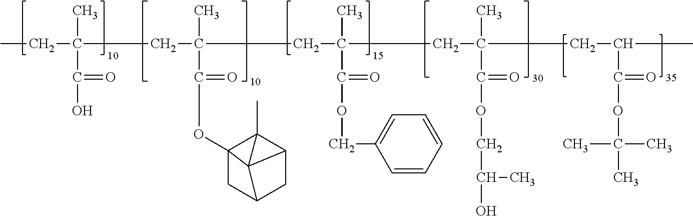

8.61 g of methacrylic acid, 22.23 g of isobornyl methacylate, 26.43 g of benzyl methacrylate, 43.25 g of hydroxypropyl methacrylate, 44.36 g of tert-butyl acrylate are mixed in 156.4 g of PGME solvent. The polymerization reaction proceeds in the presence of 2.46 g of AIBN at 90° C., under nitrogen for 18 hours. After cooling down to room temperature, the reaction mixture is precipitated in DI water. The polymer solid is washed and dried under vacuum at 45° C., yielding 142.5 g (98.3% yield) with a weight average molecular weight of 25,535 Daltons.

### Formulation Examples

### Formulation Example 1

16.1 g of acrylic polymer resin of Acrylic polymer synthesis example 11, 25.1 g of Novolak-3, 0.42 g of 1,3-dioxo-1H-benzo[de]isoquinolin-2(3H)-yl trifluoromethanesulfonate [also called naphthalene dicarboximidyl triflate, NIT] (MT PAG), 0.03 g of 1H-1,2,4-triazole-3-thiol, 0.03 g of tetrabutyl ammonium oxalate and 0.050 g of APS-437 and 0.42 g of NK-280 were dissolved in 57.85 g of PGMEA solvent to to obtain a resist solution at 42.15% solid. This solution was filtered for use.

### Formulation Example 2

16.1 g of acrylic polymer resin of Acrylic polymer synthesis example 11, 25.1 g of Novolak-3, 0.42 g of 1,3-dioxo-1H-benzo[de]isoquinolin-2(3H)-yl trifluoromethanesulfonate [also called naphthalene dicarboximidyl triflate, NIT] (NIT PAG), 0.03 g of 1H-1,2,4-triazole-3-thiol, 0.03 g of tetrabutyl ammonium oxalate and 0.050 g of APS-437 and 0.42 g of PW-898 were dissolved in 57.85 g of PGMEA solvent to obtain a resist solution at 42.15% solid. This solution was filtered for use.

### Formulation Example 3

12.3 g of acrylic polymer resin of Acrylic polymer synthesis example 11, 28.8 g of Novolak-3, 0.32 g of 1,3-dioxo-1H-benzo[de]isoquinolin-2(3H)-yl trifluoromethanesulfonate [also called naphthalene dicarboximidyl triflate, NIT] (NIT PAG), 0.03 g of 1H-1,2,4-triazole-3-thiol, 0.03 g of tetrabutyl ammonium oxalate and 0.050 g of APS-43 and 0.85 g of NK-280 were dissolved in 57.62 g of PGMEA solvent to to obtain a resist solution at 42.38% solid. This solution was filtered for use.

### Formulation Example 4

9.95 g of acrylic polymer resin of Acrylic polymer synthesis example 11, 29.8 g of Novolak-3, 0.32 g of 1,3-dioxo-1H-benzo[de]isoquinolin-2(3H)-yl trifluoromethanesulfonate [also called naphthalene dicarboximidyl triflate, NIT] (NIT PAG), 0.03 g of 1H-1,2,4-triazole-3-thiol, 0.03 g of tetrabutyl ammonium oxalate and 0.050 g of APS-437 and 2.24 g of NK-280 were dissolved in 57.58 g of PGMEA solvent to obtain a resist solution at 42.4% solid. This solution was filtered for use.

### Formulation Example 5

7.08 g of acrylic polymer resin of Acrylic polymer synthesis example 11, 32.66 g of Novolak-3, 0.20 g of 1,3-dioxo-1H-benzo[de]isoquinolin-2(3H)-yl trifluoromethanesulfonate [also called naphthalene dicarboximidyl triflate, NIT] (NIT PAG), 0.03 g of 1H-1,2,4-triazole-3-thiol, 0.03 g of tetrabutyl ammonium oxalate and 0.050 g of APS-437 and 2.17 g of NK-280 were dissolved in 57.78 g of PGMEA solvent to obtain a resist solution at 42.2% solid. This solution was filtered for use.

### Formulation Example 6

4.2 g of acrylic polymer resin of Acrylic polymer synthesis example 11, 35.49 g of Novolak-3, 0.11 g of 1,3-dioxo-1H-benzo[de]isoquinolin-2(3H)-yl trifluoromethanesulfonate [also called naphthalene dicarboximidyl triflate, NIT] (NIT PAG), 0.03 g of 1H-1,2,4-triazole-3-thiol, 0.03 g of tetrabutyl ammonium oxalate and 0.050 g of APS-437 and 2.10 g of NK-280 were dissolved in 57.99 g of PGMEA solvent to obtain a resist solution at 42.0% solid. This solution was filtered for use.

### Formulation Example 7, 8, 9, 10, 11, 12, 13, 14, 15, and 16

These formulations were prepared in the same manner as formulation example 1 but replacing Acrylic polymer synthesis example 11 with Acrylic polymer synthesis examples 1, 2, 3, 4, 5, 6, 7, 8, 9, and 10, respectively. These additional resists formulations were tested under the same processing condition mentioned below. All these resist formulations showed better PED performance compared to the formulation without diazonaphthoquinonesulfonic esters (Formulation Example 17 see below)

### Formulation Example 17 (Comparative Example)

16.5 g of acrylic polymer resin of Acrylic polymer synthesis example 11, 25.1 g of Novolak-3, 0.42 g of NIT PAG, 0.03 g of 1H-1,2,4-triazole-3-thiol, 0.03 g of tetrabutyl ammonium oxalate and 0.050 g of APS-437 were dissolved in 57.8 g of PGMEA solvent to obtain a resist solution at 42.2% solid. This solution was filtered for use. This example was used to compare with Example 1 to 16 to show the significant influence of additive of diazonaphthoquinonesulfonic esters on post exposure delay in the presence of amine.

### Lithographic Photoresist Processing

### Coating

All formulations were tested on 8″ diameter Si and Cu wafers. The Si wafers were dehydration baked and vapor primed with hexamethyldisilazane (HMDS). The Cu wafers were silicon wafers coated with 5,000 Angstroms of silicon dioxide, 250 Angstroms of tantalum nitride, and 3,500 Angstroms of Cu (PVD deposited).

The photoresist coatings were prepared by spin coating the photoresist samples and applying a soft bake for 300 seconds at 130° C. on standard wafer track hot plate in contact mode. The spin speed was adjusted to obtain 40-micron thick photoresist films. All film thickness measurements were conducted on Si wafers using optical measurements.

### Imaging

The wafers were exposed on SUSS MA200 CC Mask Aligner. The photoresist was post exposure baked at 100° C. for 100 seconds and puddle developed for 240 seconds in AZ 300 MIF (0.26N aqueous solution of tetramethyl ammonium hydroxide=TMAH) at 23° C. The developed photoresist images were inspected using Hitachi S4700 or AMRAY 4200L electron microscopes.

### Wafer Processing

The wafers were exposed on ASML 250 i-line stepper. The resist was post exposure baked at 90° C. for 60 seconds and puddle developed for 120 seconds in AZ 300 MIF (0.26N aqueous solution of tetramethyl ammonium hydroxide=TMAH) (EMD Performance Materials, AZ Products, Somerville, N.J.) at 23° C. The developed resist images were inspected using Hitachi S4700 or AMRAY 4200L electron microscopes.

All formulations were tested on 6″ diameter Si and Cu wafers. The Si wafers were dehydration baked and vapor primed with hexamethyldisilazane (HMDS). The Cu wafers were silicon wafers coated with 5,000 Angstroms of silicon dioxide, 250 Angstroms of tantalum nitride, and 3,500 Angstroms of Cu (PVD deposited).

The resist coatings were prepared by spin coating the resist samples and applying a soft bake for 180 seconds at 120° C. on standard wafer track hot plate in contact mode. The spin speed was adjusted to obtain 10 microns thick resist films. All film thickness measurements were conducted on Si wafers using optical measurements.

### Post Exposure Delay (PED) Testing

During PED testing, coated wafers, were delayed for 24 hours after UV exposure prior to being developed. Then the wafers were developed according to the same conditions of the wafer without delay. SEM was used to check the PED effect on the profile for 10 to 2 μm L/S features with a pitch of 1/1. Table 1 Summarizes these PED results. All the formulations containing a DNQ PAC showed excellent PED latitude up 24 hours. Formulations 5 and 6 also showed good PED latitude but lower L/S resolution (only down to 4.5 μm L/S for formulation 5 and 6.5 μm for Formulation 6) and is believed to be attributable to the lower wt % of PAG (0.47 and 0.26 wt % solids). This said, these formulations still showed excellent PED delay latitude for the features that could be resolved confirming the unexpected result of improved PED latitude imparted by the addition of a DNQ PAC to these formulations.

TABLE 1

| | Acrylate | | DNQ | Litho- | 24 hr. |
|---|---|---|---|---|---|
| | resins | | wt % | graphic | PED |
| Formulation | Synthesis | DNQ | solids | Perfor- | Latitude |
| Example # | Example # | type | loading | mance | Results |
| 1 | 11, | NK280 | 1.00 | ◯ | ◯ |
| 2 | 11, | PW-898 | 1.00 | ◯ | ◯ |
| 3 | 11, | NK280 | 2.00 | ◯ | ◯ |
| 4 | 11, | NK280 | 5.28 | ◯ | ◯ |
| 5 | 11, | NK280 | 5.14 | Lower | ◯ |
| | | | | resolution | |
| | | | | but able to | |
| | | | | resolve down | |
| | | | | to 4.5 μm L/S | |
| 6 | 11, | NK280 | 5.00 | Lower | ◯ |
| | | | | resolution | |
| | | | | but able to | |
| | | | | resolve down | |
| | | | | to 6.5 μm L/S | |
| 7 | 1 | NK280 | 1.00 | ◯ | ◯ |
| 8 | 2 | NK280 | 1.00 | ◯ | ◯ |
| 9 | 3 | NK280 | 1.00 | ◯ | ◯ |
| 10 | 4 | NK280 | 1.00 | ◯ | ◯ |
| 11 | 5 | NK280 | 1.00 | ◯ | ◯ |
| 12 | 6 | NK280 | 1.00 | ◯ | ◯ |
| 13 | 7 | NK280 | 1.00 | ◯ | ◯ |
| 14 | 8 | NK280 | 1.00 | ◯ | ◯ |
| 15 | 9 | NK280 | 1.00 | ◯ | ◯ |
| 16 | 10 | NK280 | 1.00 | ◯ | ◯ |
| 17 (Com- | 11 | none | 0 | ◯ | X |
| parative | | | | | |
| Example) | | | | | |

◯: For “Lithographic Performance,” this designates that the photoresist was able to resolve at least 2.2 μm L/S with a pitch of 1/1, ◯: for PED delay at least 24-hour delay without any significant change is profile.
X: for PED delay this indicates that all L/S profiles showed bad features which were 10-2.2 μm.

1. A composition comprising components a), b), c), d), and e);
a) at least one Diazonaphthoquinonesulfonate Photoactive Compound (DNQ-PAC);
b) at least one heterocyclic thiol having structure (7), (8) and/or (9),
c) at least one photoacid generator;
d) at least one acrylic polymer comprising repeat units selected from ones having structure (1), (2), (3), (4), (5), and (6), wherein
e) at least one Novolak polymer having a dissolution rate in 0.26 N tetramethylammonium hydroxide at 23° C. of at least 50 A/sec, wherein
said repeat units are present in said acrylic polymer in the following mole % ranges, based on the total moles of all different repeat units present, and further where the summation of the individual mole % values for all repeat units present in said polymer must equal 100 mole %, and
(1) ranges from about 0 to about 35 mole %
(2) ranges from about 5 to about 55 mole %
(3) ranges from about 0 to about 30 mole %
(4) ranges from about 15 to about 55 mole %
(5) ranges from about 10 to about 40 mole %,
(6) ranges from about 0 to about 25 mole %, and
R₁, R₂, R₃, R₄, R₅, and R₆ are individually selected from either H, F, a C-1 to C-4 fluoroalkyl, or a C-1 to C-4 alkyl
R₇ is selected from H, a C-1 to C-4 alkyl, a C-1 to C-4 alkyloxy alkyl, and a halogen,
R₈ is a C-3 to C-8 cyclic alkyl, or a C-7 to C-14 alicyclic alkyl,
R₉ is a C-2 to C-8 (hydroxy)alkylene moiety,
R₁₀ is an acid cleavable group,
R₁₁ is a C-3 to C-12, (alkyloxy)alkylene moiety; and
in said structure (7), Xt is selected from the group consisting of C(Rt₁)(Rt₂), 0, S, Se, and Te;
in said structure (8), Y is selected from the group consisting of C(Rt₃) and N;
in said structure (9), Z is selected from the group consisting of C(Rt₃) and N; and
Rt₁, Rt₂, and Rt₃ are independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms;

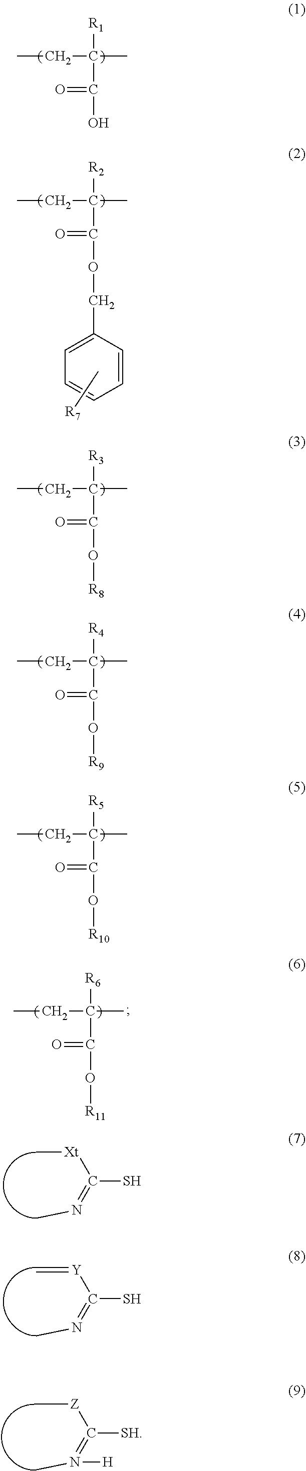

2. The composition of claim 1, wherein said DNQ-PAC is a single material or a mixture of materials in which a 2,1,5-Diazonaphthoquinonesulfonate moiety having structure (10) forms at least one sulfonate ester with a phenolic compound,

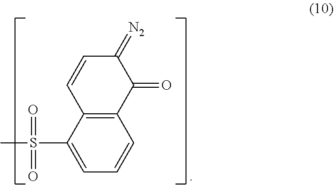

3. The composition of claim 1, wherein said DNQ PAC is a single material or a mixture of materials having general formula (11) wherein D_{1c}, D_{2c}, D_{3c} and D_{4c} are individually selected from H or a moiety having structure (10), and further wherein at least one of D_{1c}, D_{2c}, D_{3c} or D_{4c} is a moiety having structure (10),

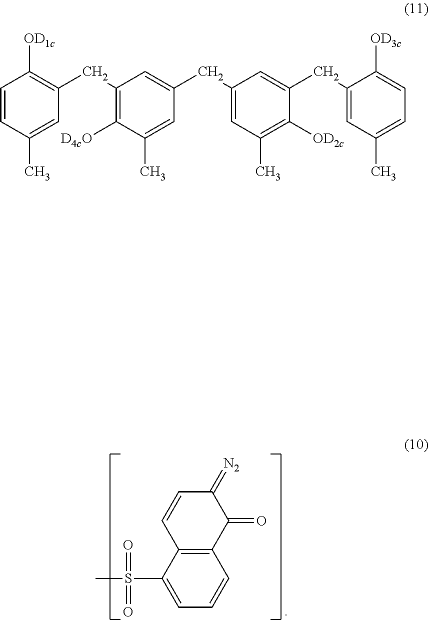

4. The composition of claims 1, wherein said DNQ PAC is either a single compound or a mixture of PAC compounds having structure (12a), wherein D₁ₑ, D₂ₑ, and D₃ₑ are individually selected from H or a moiety having structure (10), and further wherein at least one of D₁ₑ, D₂ₑ, or D₃ₑ is a moiety having structure (10),

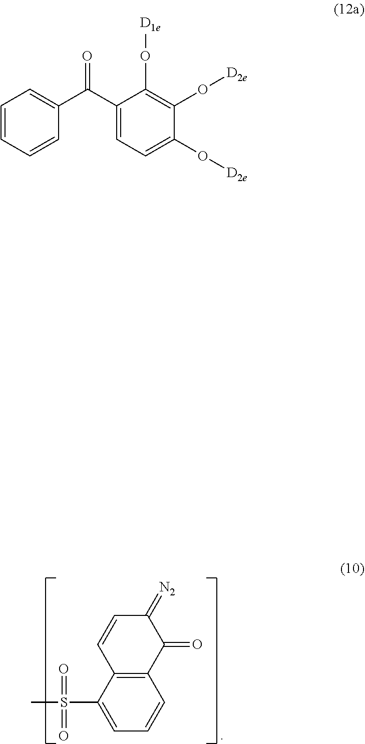

5. The composition of claim 1, wherein said DNQ PAC is either a single compound or a mixture of PAC compounds having structure (12b), wherein D₁ₑ, D₂ₑ, D₃ₑ and D₄ₑ are individually selected from H or a moiety having structure (10), and further wherein at least one of D₁ₑ, D₂ₑ, D₃ₑ or D₄ₑ is a moiety having structure (10),

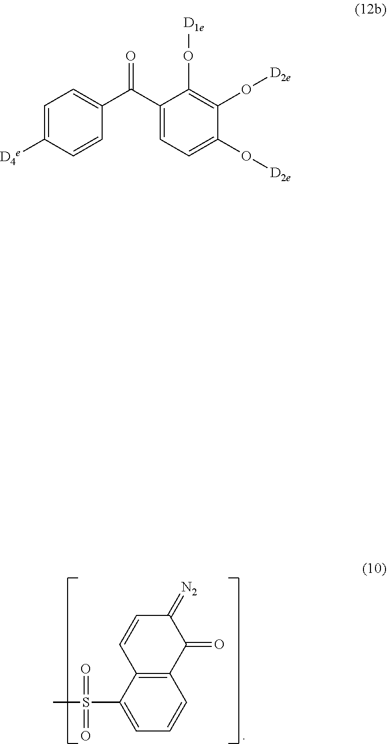

6. The composition of claim 1, wherein said DNQ PAC is either a single compound or a mixture of compounds having structure (13), wherein D_{1f}, D_{2f}, D_{3f} and D_{4f} are individually selected from H or a moiety having structure (10), and further wherein at least one of D_{1f}, D_{2f}, D_{3f} or D_{4f} is a moiety having structure (10),

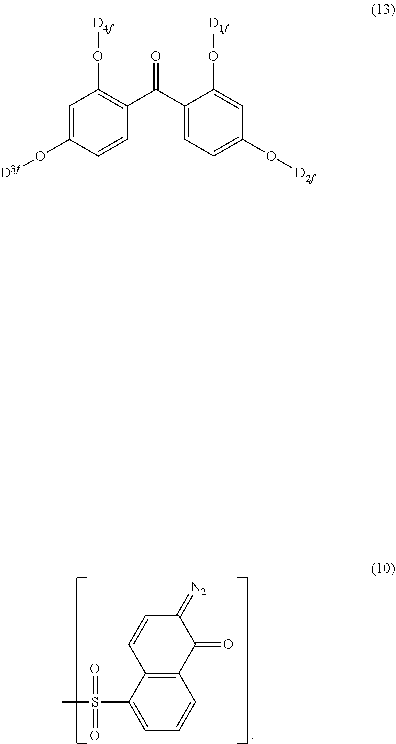

7. The composition of claim 1, wherein the heterocyclic thiol is selected from a group consisting of unsubstituted triazole thiol, substituted triazole thiol, unsubstituted imidazole thiol, substituted imidazole thiol, substituted triazine thiol, unsubstituted triazine thiol, a substituted mercapto pyrimidine, unsubstituted mercapto pyrimidine, a substituted thiadiazole-thiol, unsubstituted thiadiazole-thiol, substituted indazole thiol, unsubstituted indazole thiol, tautomers thereof, and combinations thereof.

8. The composition of claim 1, wherein the heterocyclic thiol is selected from a group consisting of 1,3,5-triazine-2,4,6-trithiol, 2-mercapto-6-methylpyrimidin-4-ol, 3-mercapto-6-methyl-1,2,4-triazin-5-ol, 2-mercaptopyrimidine-4,6-diol, 1H-1,2,4-triazole-3-thiol, 1H-1,2,4-triazole-5-thiol, 1H-imidazole-2-thiol, 1H-imidazole-5-thiol, 1H-imidazole-4-thiol, 2-azabicyclo[3.2.1]oct-2-ene-3-thiol, 2-azabicyclo[2.2.1]hept-2-ene-3-thiol, 1H-benzo[d]imidazole-2-thiol, 2-mercapto-6-methylpyrimidin-4-ol, 2-mercaptopyrimidin-4-ol, 1-methyl-1H-imidazole-2-thiol, 1,3,4-thiadiazole-2,5-dithiol, 1H-indazole-3-thiol, tautomers thereof and combinations thereof.

9. The composition of claim 1, wherein at least one photoacid generator is selected from a group consisting of an onium salt, a dicarboximidyl sulfonate ester, an oxime sulfonate ester, a diazo(sulfonyl methyl) compound, a disulfonyl methylene hydrazine compound, a nitrobenzyl sulfonate ester, a biimidazole compound, a diazomethane derivative, a glyoxime derivative, a β-ketosulfone derivative, a disulfone derivative, a sulfonic acid ester derivative, an imidoyl sulfonate derivative, and a halogenated triazine compound, or combinations thereof.

10. The composition of claim 1, wherein said acrylate polymer is one whose repeat units are selected from the group consisting of repeat units having structure (1), (2), (3), (4), (5), and (6).

11. The composition of claim 1, wherein said acrylate polymer is one whose repeat units are selected from the group consisting of repeat units having structure (1), (2), (4), (5), and (6).

12. The composition of claim 1, wherein said acrylate polymer is one wherein
(1) ranges from about 5 to about 20 mole %
(2) ranges from about 5 to about 25 mole %
(3) ranges from about 0 to about 30 mole %
(4) ranges from about 15 to about 55 mole %
(5) ranges from about 20 to about 40 mole %, and
(6) ranges from about 5 to about 25 mole %.

13. The composition of claim 1, wherein said acrylate polymer is one whose repeat units are the ones having structures (1), (2a), (4a), (5), and (6a) wherein n and n′ are the numbers of methylene spacer moieties and range, independently, from 1 to 4, R₁, R₂, R₄, R₅, and R₇, individually, are selected from a C-1 to C-4 alkyl, R_{9′} and R_{11′} are individually selected from H or a C-1 to C-4 alkyl, and R_{11″}, is a C-1 to C-4 alkyl,

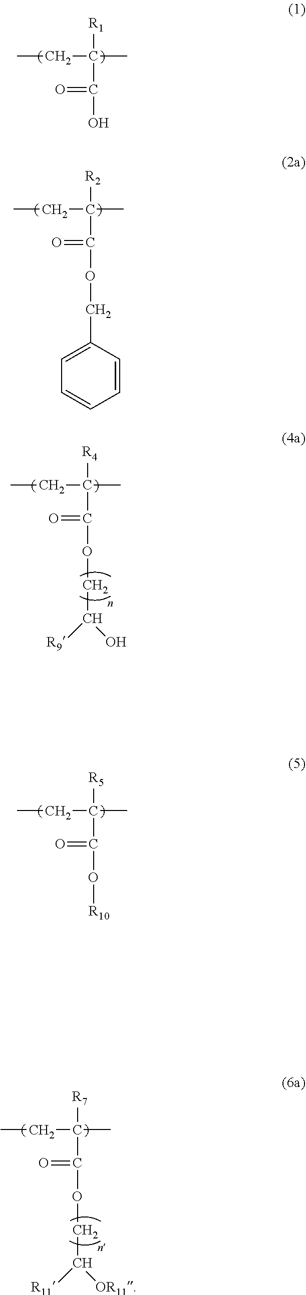

14. The composition of claim 13 wherein,
(1) ranges from about 5 to about 20 mole %
(2a) ranges from about 5 to about 25 mole %
(4a) ranges from about 15 to about 55 mole %
(5) ranges from about 20 to about 40 mole %, and
(6a) ranges from about 5 to about 25 mole %.

15. The composition of claim 1, wherein in repeat unit of structure (5), said R₁₀ acid cleavable group, is selected from the group consisting of a t-butyl group, a tetrahydropyran-2-yl group, a tetrahydrofuran-2-yl group, a 4-methoxytetrahydropyran-4-yl group, a 1-ethoxyethyl group, a 1-butoxyethyl group, a 1-propoxyethyl group, a 3-oxocyclohexyl group, a 2-methyl-2-adamantyl group, a 2-ethyl-2-adamantyl group, a 8-methyl-8-tricyclo[5.2.1.02,6]decyl group, a 1,2,7,7-tetramethyl-2-norbornyl group, a 2-acetoxymenthyl group, a 2-hydroxymethyl group a 1-methyl-1-cyclohexylethyl group, a 4-methyl-2-oxotetrahydro-2H-pyran-4-yl group, a 2,3-dimethylbutan-2-yl group, a 2,3,3-trimethylbutan-2-yl group, a 1-methyl cyclopentyl group, a 1-ethyl cyclopentyl group, a 1-methyl cyclohexyl group, 1-ethyl cyclohexyl group, a 1,2,3,3-tetramethylbicyclo[2.2.1]heptan-2-yl group, a 2-ethyl-1,3,3-trimethylbicyclo[2.2.1]heptan-2-yl group, a 2,6,6-trimethylbicyclo[3.1.1]heptan-2-yl group, a 2,3-dimethylpentan-3-yl group, or a 3-ethyl-2-methylpentan-3-yl group.

16. The composition of claim 1, wherein said acrylate polymer is one whose repeat units are the ones having structures (1), (2b), (4b), (5a), and (6b),

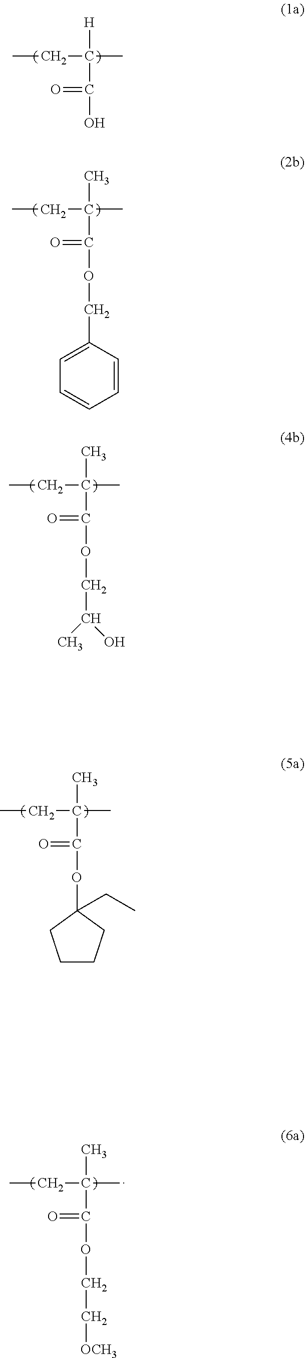

17. The composition of claim 16 wherein,
(1a) ranges from about 5 to about 20 mole %
(2b) ranges from about 5 to about 25 mole %
(4b) ranges from about 15 to about 55 mole %
(5a) ranges from about 20 to about 40 mole %, and
(6b) ranges from about 5 to about 25 mole %.

18. The composition of claim 1, wherein the polymer further comprises at least one styrenic repeat units selected from the ones having the structure (14), where R₁₄ is chosen from H, or CH₃ and R_{14′} and R_{14″} can be the same or different, and are chosen from H, OH, OCOOC(CH₃)₃, or OCOCOO(CH₃)₃.

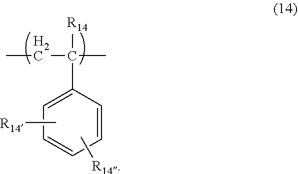

19. The composition of claim 1, wherein the polymer further comprises a (meth)acrylate of a lactone moiety which is either a single cyclic lactone or a lactone moiety comprised within an alicyclic alkyl.

20. The composition of claim 1, wherein the polymer further comprises at least one repeat unit of structure (15) comprising a lactone moiety wherein R₁₅ is chosen from H, or CH₃ and m is 1 or 2,

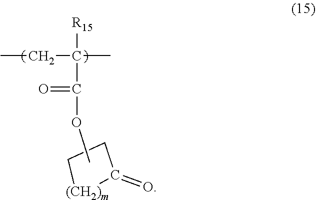

21. The composition of claim 1, wherein said Novolak resin comprises a repeat unit of structure (16) wherein, Ra and Rb are independently a C-1 to C-4 alkyl, na is 0 to 3, and nb is 0 or 1.

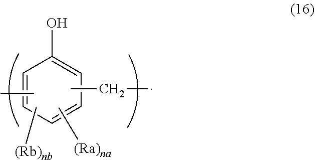

22. The composition of claim 1, wherein said Novolak resin comprises a repeat unit of structure (17) wherein, Rc is a C-1 to C-4 alkyl, Rd is a C-1 to C-4 alkyl, X is —O—, —C(CH₃)₂—, —(C═O)— or —SO₂—, nc is 0 to 3, and nd is 0 or 1.

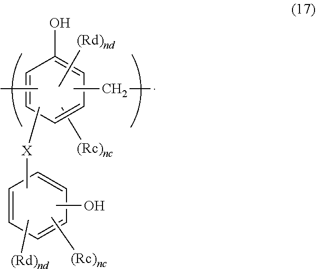

23. The composition of claim 1, wherein said Novolak resin comprises repeat units (16) and (17) wherein, Ra and Rb are independently a C-1 to C-4 alkyl, na is 0 to 3, and nb is 0 or 1 and Rc is a C-1 to C-4 alkyl, Rd is a C-1 to C-4 alkyl, X is —O—, —C(CH₃)₂—, —(C═O)— or —SO₂—, nc is 0 to 3, and nd is 0 or 1

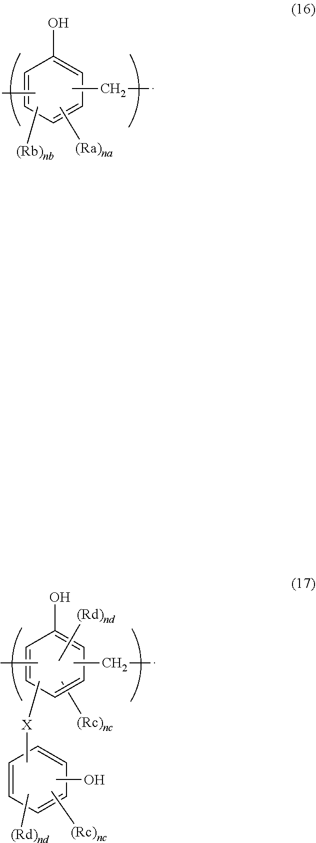

24. The composition of claim 1, wherein said Novolak resin is a m-cresol and formaldehyde Novolak resin.

25. The composition of claim 1, wherein the Novolak resin comprises from about 10 to about 90 wt % solids.

26. A method of forming a positive relief image comprising:
forming a photosensitive layer by applying the positive working photosensitive composition of claim 1 to a substrate;
image-wise exposing the photosensitive layer to actinic radiation to form a latent image;
developing the latent image in a developer,
wherein the image-wise exposed photosensitive layer is optionally thermally treated.

27. The method of claim 26 wherein the substrate comprises a chalcophile.

28. The method of claim 26 wherein the substrate is copper.

29. The use of the composition of claim 1 for forming a positive relief image on a substrate.
